(19) United States
(12) Patent Application Publication
(10) Pub. No.: US 2025/0393300 A1
(43) Pub. Date: Dec. 25, 2025

(54) INTEGRATED CIRCUIT DEVICE AND METHOD OF MANUFACTURING

(71) Applicant: TAIWAN SEMICONDUCTOR MANUFACTURING COMPANY, LTD., Hsinchu (TW)

(72) Inventors: Wei-Cheng TZENG, Hsinchu (TW); Chun-Yen LIN, Hsinchu (TW); Wei-Cheng LIN, Hsinchu (TW); Jiann-Tyng TZENG, Hsinchu (TW)

(21) Appl. No.: 18/912,171

(22) Filed: Oct. 10, 2024

Related U.S. Application Data
(60) Provisional application No. 63/663,413, filed on Jun. 24, 2024.

(51) Int. Cl. H01L 27/092; H01L 21/768; H01L 23/528; H01L 29/06; H01L 29/417; H01L 29/423; H01L 29/775; H01L 29/786

(52) U.S. Cl. CPC H10D 84/856; H01L 21/76877; H01L 23/528; H10D 30/6729; H10D 30/43; H10D 30/6735; H10D 30/6757; H10D 62/121

(57) ABSTRACT

An integrated circuit (IC) device includes a device stack, a top contact structure, a bottom contact structure, a conductor, a via interconnect, and a back side power rail. The device stack includes a bottom semiconductor device, and a top semiconductor device stacked over the bottom semiconductor device along a thickness direction. The top contact structure is over and in electrical contact with a source/drain of the top semiconductor device. The bottom contact structure is under and in electrical contact with a source/drain of the bottom semiconductor device. The conductor is co-elevational with, and spaced from, the bottom contact structure. The via interconnect extends between and electrically couples the top contact structure and the conductor. The back side power rail is under and electrically coupled to the conductor.

### RELATED APPLICATION(S)

This application claims the benefit of U.S. Provisional Application No. 63/663,413, filed Jun. 24, 2024, which is herein incorporated by reference in its entirety.

### BACKGROUND

An integrated circuit (“IC”) device includes one or more semiconductor devices represented in an IC layout diagram (also referred to as “layout diagram,” “layout” or “IC layout”). A layout diagram is hierarchical and includes modules which carry out higher-level functions in accordance with the semiconductor device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs.

To reduce the sizes of IC devices, sometimes a layer of semiconductor devices is formed, or bonded, over another layer of semiconductor devices. Examples include complementary field effect transistor (CFET) devices in which an upper or top semiconductor device overlies a lower or bottom semiconductor device in a stack configuration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic perspective view of a stack of semiconductor devices, in accordance with some embodiments.

FIG. 1B is a schematic perspective view, and FIGS. 1C, 1D, 1E and 1F are schematic cross-sectional views of an IC device at various stages in a manufacturing process, in accordance with some embodiments.

FIG. 2A is a block diagram of an IC device, in accordance with some embodiments.

FIG. 2B is a schematic view of a layout an IC device, in accordance with some embodiments.

FIGS. 3A and 3B are schematic cross-sectional views of various circuit regions of one or more IC devices, in accordance with some embodiments.

FIGS. 4A and 4B are schematic perspective views of various circuit regions of one or more IC devices, in accordance with some embodiments.

FIG. 5 is a schematic view of a layout of a circuit region of an IC device, in accordance with some embodiments.

FIG. 6 is a schematic perspective view of a circuit region of an IC device, in accordance with some embodiments.

FIGS. 7A, 7B, 7C, 7D and 7E each include a schematic circuit diagram of a circuit region and schematic views at various layers of a layout of the circuit region, in accordance with some embodiments.

FIGS. 8A and 8B each include a schematic diagram of a portion of an IC manufacturing process, and schematic views of an IC device at various stages in the manufacturing process, in accordance with some embodiments.

FIGS. 9A-9D are flowcharts of various methods, in accordance with some embodiments.

FIG. 10 is a block diagram of an electronic design automation (EDA) system in accordance with some embodiments.

FIG. 11 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an IC device includes a power delivery structure configured to provide various power supply voltages, e.g., a positive power supply voltage VDD and a reference voltage such as the ground voltage VSS, to various circuits and/or circuit components of the IC device. In some configurations, the power delivery structure is arranged at both a front side and an opposite, back side of the IC device, and comprises one or more power tap structures configured to provide power from one of the front side and the back side to the other side. A chip area occupied by power tap structures or power tap cells is sometimes referred to as a power tap area.

In some embodiments, a via interconnect is embedded in a circuit of an IC device, and is configured to deliver power or a signal from one side of the IC device to the other side, e.g., from the back side to the front side. In at least one embodiment, the via interconnect is embedded in a dielectric structure that limits or defines a length of one or more gates in the circuit. In some embodiments, the via interconnect is arranged on a boundary of a first cell corresponding to the circuit, and is configured to be shared with a further circuit corresponding to a second cell placed in abutment with the first cell. In one or more embodiments where the via interconnect is configured to deliver power from one side of the IC device to the other side, it is possible to eliminate all power tap structures, or at least reduce the number of power tap structures, in the IC device. As a result, in one or more embodiments, the power tap area of the IC device is advantageously reduced, while ensuring that a voltage drop (or IR drop) in the power delivery structure is within a predetermined or acceptable range. In one or more embodiments where the via interconnect is configured to deliver a signal from one side of the IC device to the other side, routing resources in one or more metal layers and/or via layers are advantageously freed up. One or more further advantages are achievable in various embodiments, as described herein.

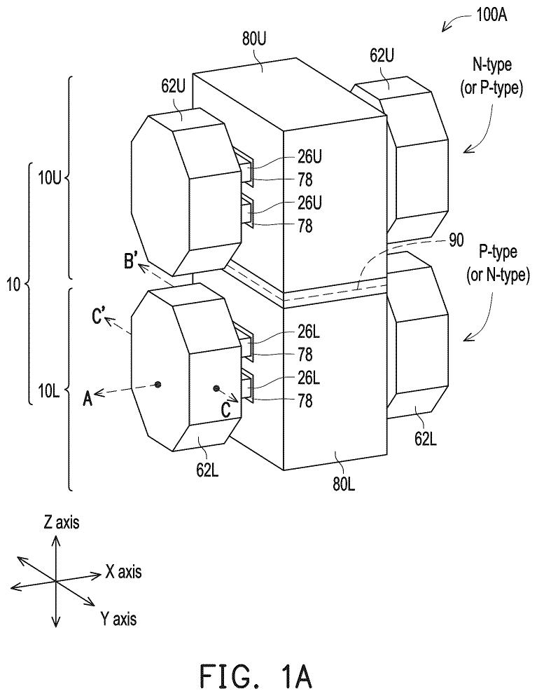

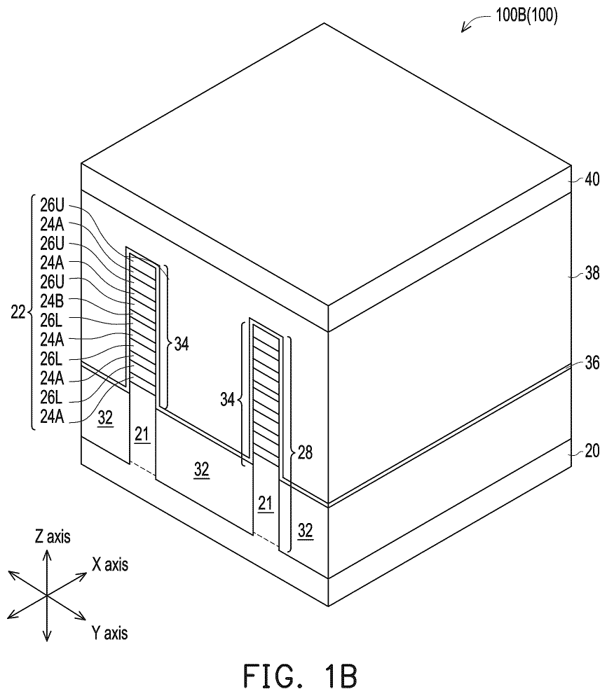

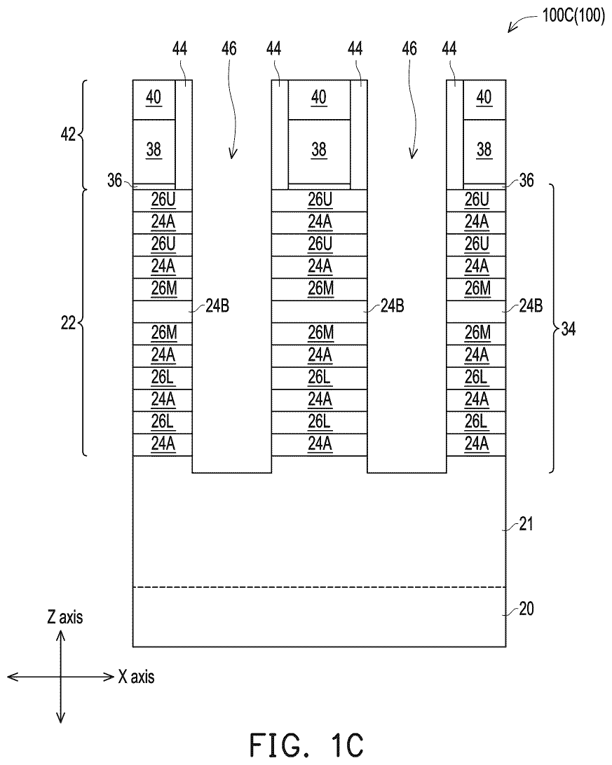

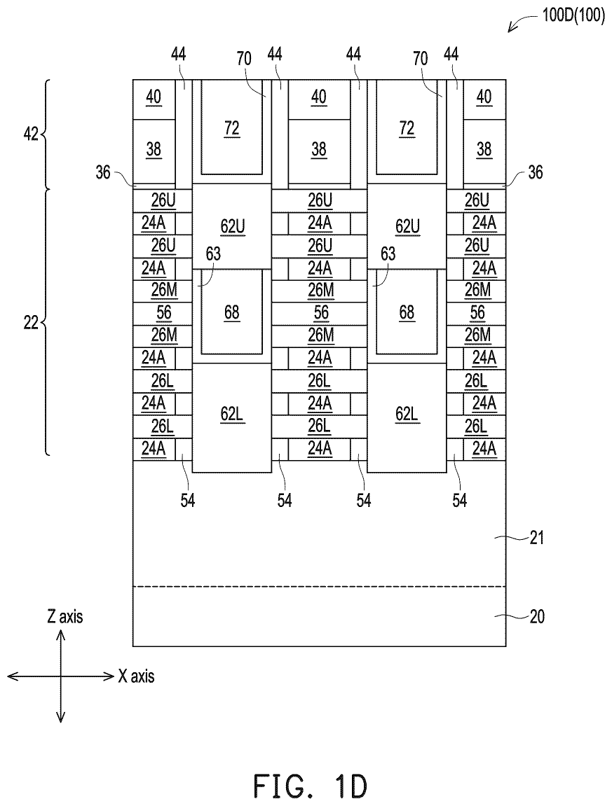

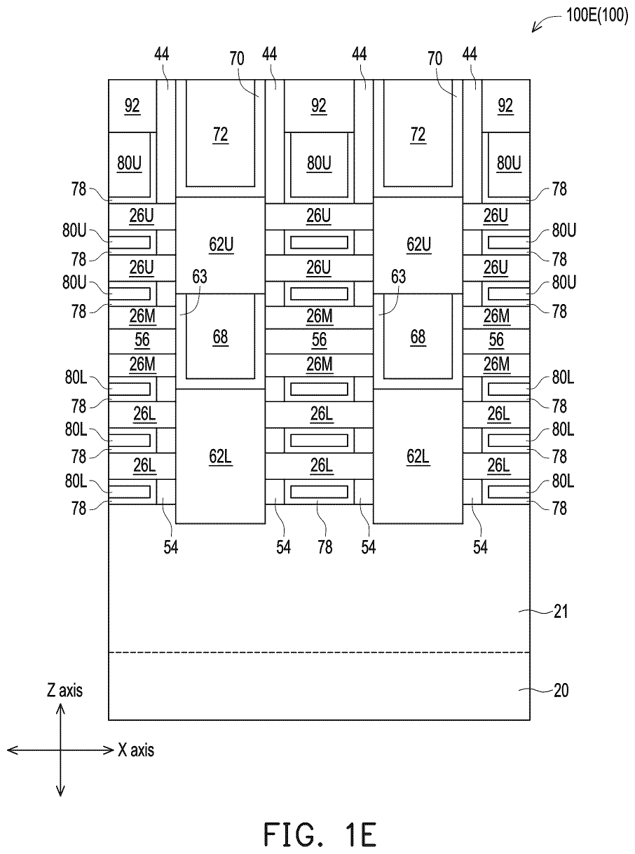

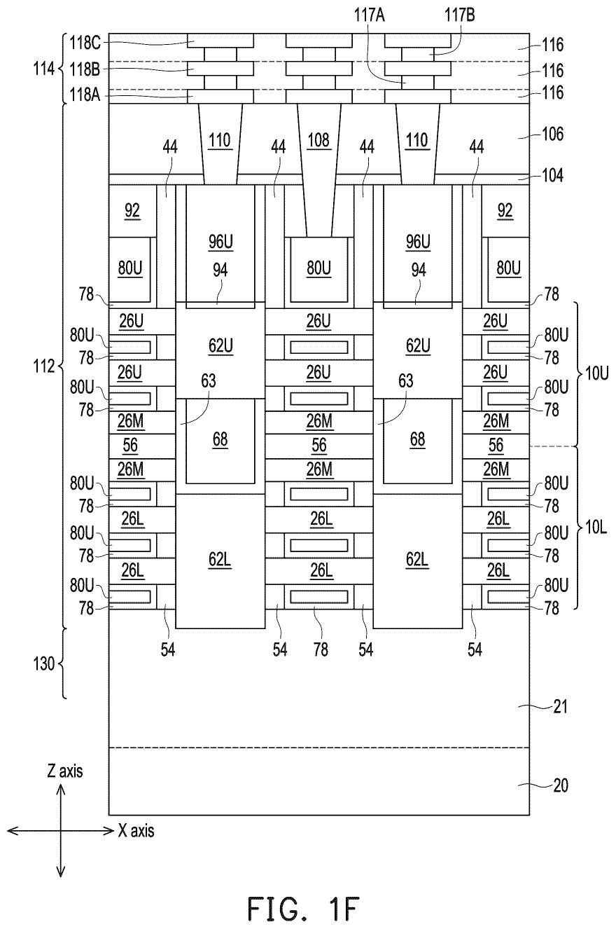

FIG. 1A is a schematic perspective view of a stack of semiconductor devices, or a device stack, 100A, in accordance with some embodiments.

The device stack 100A comprises a stacked structure 10 of a bottom semiconductor device 10L and a top semiconductor device 10U. The bottom semiconductor device 10L is over a substrate. For simplicity, the substrate is not illustrated in FIG. 1A. An example substrate is described with respect to FIGS. 1B-1F. The top semiconductor device 10U is physically stacked over the bottom semiconductor device 10L in a thickness direction of the substrate. The thickness direction is designated as a Z axis in FIG. 1A. In the example configuration in FIG. 1A, the top semiconductor device 10U and the bottom semiconductor device 10L are of different conductivity types. Other configurations where both top semiconductor device 10U and bottom semiconductor device 10L are of the same conductivity type are within the scopes of various embodiments. Conductivity type is sometimes referred to as semiconductor type. Examples of conductivity type include N-type and P-type. In an example, the top semiconductor device 10U is an N-type semiconductor device, the bottom semiconductor device 10L is a P-type semiconductor device, and the stacked structure 10 is referred to as an N-on-P structure. In another example, the top semiconductor device 10U is a P-type semiconductor device, the bottom semiconductor device 10L is an N-type semiconductor device, and the stacked structure 10 is referred to as a P-on-N structure. For simplicity, various example embodiments described herein include N-on-P structures. One or more features, functions and/or advantages of embodiments with N-on-P structures are applicable to and/or achievable in embodiments with P-on-N structures.

Examples of semiconductor devices include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like. In the example configuration in FIG. 1A, the top semiconductor device 10U and bottom semiconductor device 10L are nanosheet FETs. Other semiconductor device configurations are within the scopes of various embodiments. In some embodiments, the top semiconductor device 10U and bottom semiconductor device 10L have different semiconductor device configurations. For example, the bottom semiconductor device 10L is a planar MOS transistor whereas the top semiconductor device 10U is a nanosheet FET.

The top semiconductor device 10U comprises a gate 80U, and source/drains 62U on opposite sides of the gate 80U along an X axis. The gate 80U extends, or is elongated, along a Y axis. The X axis, Y axis, Z axis are mutually transverse to each other. In some embodiments, the X axis, Y axis, Z axis are mutually perpendicular to each other. The top semiconductor device 10U further comprises a channel region configured by nanosheets 26U which extend along the X axis and connect the source/drains 62U. In the example configuration in FIG. 1A, the top semiconductor device 10U comprises two nanosheets 26U. Other numbers of nanosheets per transistor are within the scopes of various embodiments. The top semiconductor device 10U comprises a gate dielectric layer 78 extending around each of the nanosheets 26U, and electrically isolating the gate 80U from the nanosheets 26U. The gate 80U extends around the gate dielectric layer 78 and nanosheets 26U in a configuration referred to as a gate-all-around (GAA) configuration. Other gate configurations are within the scopes of various embodiments.

The bottom semiconductor device 10L comprises a gate 80L, source/drains 62L, a channel region configured by nanosheets 26L, and a gate dielectric layer 78 extending around each of the nanosheets 26L. The gate 80L, source/drains 62L, and nanosheets 26L correspond to the gate 80U, source/drains 62U, and nanosheets 26U. The gate 80U, source/drains 62U, and nanosheets 26U correspondingly overlap the gate 80L, source/drains 62L, and nanosheets 26L along the Z axis. In the example configuration in FIG. 1A, the source/drains 62U, 62L are epitaxy structures of different conductivity types. For example, the source/drains 62L are P-type epitaxy structures, and the source/drains 62U are N-type epitaxy structures.

The stacked structure 10 further comprises an intermediate layer 90 between the gate 80U and gate 80L. In some embodiments, the intermediate layer 90 is a dielectric layer electrically isolating the gate 80U from the gate 80L, in a configuration referred to as an isolated gate configuration in which the gate 80U and gate 80L are controllable independently from each other. In at least one embodiment, the gate 80U and the gate 80L in an isolated gate configuration are still electrically coupled to each other by a conductor, e.g., a gate local interconnect (MGLI). In some embodiments, the intermediate layer 90 is a conductive layer electrically coupling the gate 80U to the gate 80L, in a configuration referred to as a connected gate configuration in which the electrically coupled gate 80U and gate 80L form a common gate for both top semiconductor device 10U and bottom semiconductor device 10L. In a connected gate configuration in accordance with some embodiments, the conductive intermediate layer 90 is formed integrally, and/or simultaneously, with the gate 80U and gate 80L in a single GAA structure.

As can be seen from FIG. 1A, in one or more embodiments, the stacking of the top semiconductor device 10U over the bottom semiconductor device 10L saves about 50% of the required chip area, compared to other approaches without stacking of semiconductor devices. In some embodiments, it is possible to manufacturing an IC device comprising multiple device stacks by CFET processes, with little or no changes to the manufacturing processes.

FIG. 1B is a schematic perspective view, and FIGS. 1C-1F are schematic cross-sectional views, in an X-Z plane, of an IC device 100 at various stages in a manufacturing process, in accordance with some embodiments. The IC device 100 comprises a plurality of device stacks corresponding to the device stack 100A. For simplicity, corresponding components in FIGS. 1A-1F are designated by the same reference numerals. In some embodiments, additional operations are provided before, during, and/or after the manufacturing process described with respect to FIGS. 1B-1F, and/or one or more of the described operations are replaced or eliminated, and or the order of the operations is interchangeable.

Referring to FIG. 1B, the manufacturing process starts from a substrate 20. In at least one embodiment, the substrate 20 is a semiconductor substrate. In some embodiments, the substrate 20 includes a single crystalline semiconductor layer on at least the surface of the substrate 20. Example materials of the substrate 20 include, but are not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). For example, the substrate 20 is a Si substrate. In some embodiments, the substrate 20 is a silicon-on-insulator (SOI) substrate, which includes an insulating layer disposed between two silicon layers. In at least one embodiment, the insulating layer is an oxide layer.

A multilayer structure 22 is formed over the substrate 20. In FIG. 1B, the multilayer structure 22 is illustrated in a state after formation of fins, as described herein. The multilayer structure 22 comprises alternatingly arranged first semiconductor layers 24A, 24B and second semiconductor layers 26U, 26L. The second semiconductor layers 26U, 26L correspond to the nanosheets described with respect to FIG. 1A, and are referred to herein by the same reference numerals of the nanosheets, for simplicity. The first semiconductor layers 24A, 24B and the second semiconductor layers 26U, 26L comprise semiconductor materials having different etch selectivity and/or oxidation rates. For example, the first semiconductor layers 24A, 24B comprise SiGe, and the second semiconductor layers 26U, 26L comprise Si. In some embodiments, the first and second semiconductor layers 24A, 24B, 26U, 26L are formed by a deposition process, such as epitaxy. For example, epitaxial growth of the layers of the multilayer structure 22 is performed by a molecular beam epitaxy (MBE) process, a metalorganic chemical vapor deposition (MOCVD) process, and/or other suitable epitaxial growth processes.

Subsequent to the formation of the multilayer structure 22, fins 28 are formed. Each fin 28 comprises a substrate portion 21 of the substrate 20, and a portion 34 of the multilayer structure 22. The portion 34 of the multilayer structure 22 is sometimes referred to as a stack of semiconductor layers 34. In some embodiments, the fins 28 are fabricated using suitable processes, such as double-patterning or multi-patterning processes. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers are then used to pattern the fins 28 by etching the multilayer structure 22 and the substrate 20. Example etch processes include, but are not limited to, dry etch, wet etch, reactive ion etch (RIE), and/or other suitable processes. In FIG. 1B, two fins 28 are illustrated; however, the number of the fins is not limited to two. The fins 28 extend, or are elongated, along the X axis.

A shallow trench isolation (STI) 32 of an insulating material is formed over the substrate 20 and in trenches (not numbered) between the fins 28. For example, the insulating material is deposited over the substrate 20 and the fins 28. Example insulating materials of the STI 32 include, but are not limited to, silicon oxide, fluorine-doped silicate glass (FSG), silicon nitride, silicon oxynitride (SiON), SiOCN, SiCN, a low-k dielectric material, or the like. The deposition of the insulating material includes a suitable method, such as low-pressure chemical vapor deposition (LPCVD), plasma enhanced CVD (PECVD) or flowable CVD (FCVD). Then, a planarization operation, such as a chemical mechanical polishing (CMP) process and/or an etch-back process, is performed such that the tops of the fins 28 are exposed from the insulating material. A portion of the insulating material between adjacent fins 28 is removed. The remaining portion of the insulating material configures the STI 32. The partial removal of the insulating material includes dry etch, wet etch, or the like.

A sacrificial gate dielectric layer 36, a sacrificial gate electrode layer 38, and a mask structure 40 are deposited over the STI 32 and fins 28. The sacrificial gate dielectric layer 36 comprises one or more layers of dielectric material, such as SiO2, SiN, a high-k dielectric material, and/or other suitable dielectric material. In some embodiments, the sacrificial gate dielectric layer 36 is deposited by a CVD process, a sub-atmospheric CVD (SACVD) process, a FCVD process, an atomic layer deposition (ALD) process, a physical vapor deposition (PVD) process, or other suitable process. In at least one embodiment, the sacrificial gate electrode layer 38 comprises polycrystalline silicon (polysilicon). In some embodiments, the mask structure 40 comprises a multilayer structure. In some embodiments, the sacrificial gate electrode layer 38 and the mask structure 40 are formed by one or more processes such as layer deposition, for example, CVD (including both LPCVD and PECVD), PVD, ALD, thermal oxidation, e-beam evaporation, or other suitable deposition techniques. A structure 100B is obtained.

Referring to FIG. 1C, sacrificial gate stacks 42 are formed by one or more pattern and/or etch processes performed on the deposited sacrificial gate dielectric layer 36, sacrificial gate electrode layer 38, and mask structure 40 of the structure 100B. An example pattern process comprises a lithography process. An example etch process comprises dry etch (e.g., RIE), wet etch, other etch methods, and/or combinations thereof. Each sacrificial gate stack 42 comprises a portion of each of the sacrificial gate dielectric layer 36, sacrificial gate electrode layer 38, and mask structure 40. The sacrificial gate stacks 42 extend, or are elongated, along the Y axis. In FIG. 1C, three sacrificial gate stacks 42 are illustrated; however, the number of the sacrificial gate stacks 42 is not limited to two.

Spacers 44 are formed on sidewalls of the sacrificial gate stacks 42. For example, the spacers 44 are formed by first depositing a conformal layer that is subsequently etched back to form the spacers 44. The spacers 44 comprises a dielectric material, such as silicon oxide, silicon nitride, silicon carbide, silicon oxynitride, SiCN, silicon oxycarbide, SiOCN, and/or combinations thereof. In some embodiments, the spacers 44 comprise multiple layers.

Exposed portions of the stacks of semiconductor layers 34 of the fins 28 not covered by the sacrificial gate stacks 42 and the spacers 44 are selectively removed, e.g., by one or more suitable etch processes, such as dry etch, wet etch, or a combination thereof, to form trenches 46. In FIG. 1C, a lower most one of the second semiconductor layers 26U and an uppermost one of the second semiconductor layers 26L are designated as middle second semiconductor layers 26M which sandwich therebetween a middle first semiconductor layer 24B. The middle second semiconductor layers 26M and the middle first semiconductor layer 24B are not configured to form channel regions of the top semiconductor device 10U and bottom semiconductor device 10L. Edge portions of the first semiconductor layers 24A, 24B and second semiconductor layers 26U, 26L, 26M are exposed in the trenches 46. The trenches 46 also expose portions of the substrate portion 21. A structure 100C is obtained.

Referring to FIG. 1D, the exposed edge portions of the first semiconductor layers 24A are removed. In some embodiments, the removal comprises a selective wet etch process. The selective wet etch process further completely (or substantially completely) removes the first semiconductor layer 24B in the middle of the stack of semiconductor layers 34. For example, in embodiments where the first semiconductor layers 24A, 24B comprise SiGe, and the second semiconductor layers 26U, 26L, 26M comprise Si, a selective wet etch is configured to etch the first semiconductor layer 24B at a highest etch rate, the first semiconductor layers 24A at a second highest etch rate, and the second semiconductor layers 26U, 26L, 26M at a slowest etch rate. As a result, the exposed edge portions of the first semiconductor layers 24A and an entirety (or substantially an entirety) of the first semiconductor layer 24B are removed, whereas the second semiconductor layers 26U, 26L, 26M are substantially unchanged.

A dielectric material is deposited over and into the spaces created by the removal of the first semiconductor layer 24B and the partial removal of the edge portions of the first semiconductor layers 24A. The dielectric material filling in the spaces created by the partial removal of the edge portions of the first semiconductor layers 24A configures inner spacers 54. The dielectric material filling in the space created by the removal of the first semiconductor layer 24B configures an inner isolation structure 56. Examples of the dielectric material forming the inner spacers 54 and inner isolation structure 56 include, but are not limited to, a low-k dielectric material, such as SiO2, SiN, SiCN, SiOC, or SiOCN, or a high-k dielectric material, such as HfO2, ZrOx, ZrAlOx, HfAlOx, HfSiOx, AlOx, or other suitable dielectric material. In some embodiments, the inner spacers 54 and inner isolation structure 56 comprise different dielectric materials. In an example process, the inner spacers 54 and inner isolation structure 56 are formed by depositing a conformal layer of the dielectric material, using a conformal deposition process, such as ALD, followed by an anisotropic etching to remove portions of the conformal layer other than the inner spacers 54 and inner isolation structure 56.

Source/drain 62L are formed over, and in contact with, the exposed portions of the substrate portions 21, and exposed edge portions of the second semiconductor layers 26L. In the example configuration in FIG. 1D, the source/drains 62L comprise epitaxy structures and are sometimes referred to as source/drain epitaxy structures 62L. In some embodiments, the source/drain epitaxy structures 62L comprise one or more layers of Si, SiGe, Ge to configure a P-type bottom semiconductor device. Example epitaxial growth processes for growing the source/drain epitaxy structures 62L include, but are not limited to, CVD, ALD, MBE. In some embodiments, source/drain epitaxy structures 62L are grown to a height above the uppermost second semiconductor layer 26L, and then top portions of the source/drain epitaxy structures 62L are partially removed, e.g., by a dry etch or wet etch, so that upper surfaces of the remaining source/drain epitaxy structures 62L are at a level of the uppermost first semiconductor layer 24A immediately under the lower middle second semiconductor layer 26M, as illustrated in FIG. 1D.

A liner 63 is formed at least over the upper surfaces of the source/drain epitaxy structures 62L, and exposed side faces of the middle second semiconductor layers 26M, inner isolation structure 56. In some embodiments, the liner 63 comprises Si. In an example process, the liner 63 is a conformal layer formed by a conformal process, such as an ALD process.

A dielectric material 68 is formed over the liner 63 and over the source/drain epitaxy structures 62L. In some embodiments, the dielectric material 68 comprises the same material as the STI 32 and/or is formed by the same method as the STI 32. The liner 63 and dielectric material 68 are removed outside the trenches 46, and partially removed inside the trenches 46, e.g., by a dry etch or wet etch. As a result, upper surfaces of the liner 63 and dielectric material 68 are at a level of the lowermost first semiconductor layer 24A immediately above the upper middle second semiconductor layer 26M, as illustrated in FIG. 1D. The liner 63 and dielectric material 68 configure an isolation structure between the source/drain 62L and source/drains 62U to be subsequently formed thereover.

Source/drain 62U are formed over, and in contact with, the upper surfaces of the liner 63 and dielectric material 68, and exposed edge portions of the second semiconductor layers 26U. In the example configuration in FIG. 1D, the source/drains 62U comprise epitaxy structures and are sometimes referred to as source/drain epitaxy structures 62U. The source/drain epitaxy structures 62U are of a conductivity type different from that of the source/drain epitaxy structures 62L. In some embodiments, the source/drain epitaxy structures 62U are manufactured by the same or similar manufacturing processes as/to the source/drain epitaxy structures 62L. In at least one embodiment, the source/drain epitaxy structures 62U have the same configuration, e.g., the same size, shape, height, as the source/drain epitaxy structures 62L. In an example, the source/drain epitaxy structures 62U comprise one or more layers of Si, SiP, SiC and SiCP to configure an N-type top semiconductor device. In some embodiments, source/drain epitaxy structures 62U are grown to a height above the sacrificial gate dielectric layer 36, and then top portions of the source/drain epitaxy structures 62U are partially removed, e.g., by a dry etch or wet etch, so that upper surfaces of the remaining source/drain epitaxy structures 62U are at a level of the sacrificial gate dielectric layer 36, as illustrated in FIG. 1D. This is an example, and a height of the source/drain epitaxy structures 62U is controllable depending on application and/or process requirements.

A contact etch stop layer (CESL) 70 is formed over the source/drain epitaxy structures 62U. Example materials of the CESL 70 include, but are not limited to, silicon nitride, silicon carbon nitride, silicon oxynitride, carbon nitride, silicon oxide, silicon carbon oxide, the like, or a combination thereof. The CESL 70 is formed by CVD, PECVD, ALD, or any suitable deposition technique.

An interlayer dielectric (ILD) layer 72 is formed over the CESL 70. Example materials of the ILD layer 72 include, but are not limited to, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 72 is deposited by a PECVD process or other suitable deposition technique. A structure 100D is obtained.

Referring to FIG. 1E, a planarization process, such as a CMP process, is performed to remove the mask structure 40 and expose the sacrificial gate electrode layer 38. The planarization process also removes portions of the ILD layer 72 and the CESL 70.

The exposed sacrificial gate electrode layer 38 and the sacrificial gate dielectric layer 36 are removed, e.g., by one or more suitable processes, such as dry etch, wet etch, or a combination thereof.

Next, the first semiconductor layers 24A are removed, e.g., by any suitable processes, such as dry etch, wet etch, or a combination thereof. The removal of the first semiconductor layers 24A exposes the inner spacers 54 and the second semiconductor layers 26U, 26L, and creates spaces between and around exposed portions of the second semiconductor layers 26U, 26L not covered by the inner spacers 54. The exposed portions of the second semiconductor layers 26U, 26L configure the nanosheets 26U, 26L described with respect to FIG. 1A. The middle second semiconductor layers 26M and inner isolation structure 56 are covered by the liner 63 and dielectric material 68, and are substantially unaffected by the removal of the first semiconductor layers 24A.

A gate dielectric layer 78 is formed over and around each of the nanosheets 26U, 26L. In some embodiments, the gate dielectric layer 78 comprises the same material as the sacrificial gate dielectric layer 36. In some embodiments, the gate dielectric layer 78 comprises a high-k dielectric material. In some embodiments, the gate dielectric layer 78 is formed by a conformal process, such as an ALD process.

A gate electrode material is formed over and around the gate dielectric layers 78, and the nanosheets 26U, 26L. The gate electrode material surrounding each of the nanosheets 26U configures the gate 80U. The gate electrode material surrounding each of the nanosheets 26L configures the gate 80L. In some embodiments, the gate electrode material comprises multiple gate electrode layers. Example gate electrode materials include, but are not limited to, polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. In some embodiments, the gate electrode material comprises a P-type gate electrode layer, such as TiN, TaN, TiTaN, TiAlN, WCN, W, Ni, Co, or other suitable material, for configuring P-type bottom semiconductor devices. In at least one embodiment, the gate electrode material comprises an N-type gate electrode layer, such as TiAlC, TaAlC, TiSiAlC, TiC, TaSiAlC, or other suitable material, for configuring N-type top semiconductor devices. Example processes for depositing the gate electrode material include, but are not limited to, PVD, CVD, ALD, electro-plating, or other suitable methods.

In some embodiments, each of the gate 80U and gate 80L comprises a corresponding GAA structure, and the gate 80U and gate 80L are physically and electrically separated from each other by the middle second semiconductor layers 26M and inner isolation structure 56. In some embodiments, a combination of the middle second semiconductor layers 26M and inner isolation structure 56 corresponds to the intermediate layer 90 being a dielectric material in an isolated gate configuration. In at least one embodiment, the gate 80U and the gate 80L in an isolated gate configuration are still electrically coupled to each other by a conductor, e.g., an MGLI interconnect. In some embodiments, the gate 80U and gate 80L are integral parts of a GAA structure which extends around each of the nanosheets 26U, 26L, and configures a common gate for both top semiconductor device and bottom semiconductor device. The formation of the gate 80U and gate 80L completes the formation of the top semiconductor device 10U and bottom semiconductor device 10L. An ILD layer 92 similar to the ILD layer 72 is deposited over the gate 80U, and a planarization process, such as a CMP, is performed. A structure 100E is obtained.

Referring to FIG. 1F, openings are formed in the ILD layer 72 to expose the source/drain epitaxy structures 62U. A silicide layer 94 is formed over the exposed source/drain epitaxy structures 62U, and then source/drain contacts 96U are form in each opening and over the silicide layer 94. Source/drain contacts (or source/drain contact structures) are sometimes referred to as metal-to-device (MD) contacts. Source/drain contacts of top semiconductor devices are sometimes referred to as MD contacts or top contact structures. Source/drain contacts of bottom semiconductor devices are sometimes referred to as BMD contacts or bottom contact structures. For simplicity, an MD contact, or a contact structure, herein refers to either an MD contact at the upper layer or a BMD contact at the lower layer, unless specified otherwise. Example materials of the source/drain contacts 96U include, but are not limited to, Ru, Mo, Co, Ni, W, Ti, Ta, Cu, Al, TiN and TaN. The source/drain contacts 96U are formed by any suitable process, such as PVD, ECP, or CVD.

Dielectric layers 104, 106 are deposited over the MD contacts 96U and ILD layer 92. Various vias 108, 110 are formed by etching via openings in the dielectric layers 104, 106 and ILD layer 92, and then filling the via openings with a conductive material, such as a metal. A via over and in electrical contact with an MD contact is sometimes referred to as via-to-device (VD) via. A via over and in electrical contact with a gate is sometimes referred to as via-to-gate (VG) via. In the example configuration in FIG. 1F, the via 108 is a VG via which is over the gate 80U, and the vias 110 are VD vias correspondingly over the MD contacts 96U. VG and VD vias for bottom semiconductor devices are sometimes correspondingly referred to as BVG and BVD vias.

In some embodiments, the formation of structures up to and including the VG, VD vias completes a front-end-of-line (FEOL) fabrication. A resulting FEOL structure 112 comprising various semiconductor devices formed over a front side (or upper side) of the substrate 20 and the corresponding MD contacts, VG and VD vias is obtained. The FEOL fabrication is followed by a Back End of Line (BEOL) fabrication to provide routing for the semiconductor devices.

The BEOL fabrication comprises forming a redistribution structure 114 over the VD, VG vias 110, 108. The redistribution structure 114 comprises a plurality of metal layers 118A-118C and via layers 117A, 117B sequentially and alternatingly formed over the VD, VG vias 110, 108. The redistribution structure 114 further comprises various interlayer dielectric (ILD) layers 116 in which the metal layers and via layers are embedded. The metal layers and via layers of the redistribution structure 114 are configured to electrically couple various semiconductor devices, or circuits of the IC device 100 with each other, and/or with external circuitry. In the redistribution structure 114, the lowermost metal layer 118A immediately over and in electrical contact with the VD, VG vias 110, 108 is an M0 (metal-zero) layer, a next metal layer 118B immediately over the M0 layer is an M1 layer, a next metal layer 118C immediately over the M1 layer is an M2 layer, or the like. Conductive patterns in the M0 layer are referred to as M0 conductive patterns, conductive patterns in the M1 layer are referred to as M1 conductive patterns, or the like. A via layer Vn is arranged between and electrically couple the Mn layer and the Mn+1 layer, where n is an integer from zero and up. For example, the via layer 117A is a via-zero (V0) layer which is the lowermost via layer arranged between and electrically couple the M0 layer 118A and the M1 layer 118B. The next via layer 117B is a V1 layer which is the via layer arranged between and electrically couple the M1 layer 118B and the M2 layer 118C. Vias in the V0 layer are referred to as V0 vias, vias in the V1 layer are referred to as V1 vias, or the like. For simplicity, metal layers and via layers in the redistribution structure 114 are not fully illustrated in FIG. 1F. The redistribution structure 114 and interconnects therein are formed over the front side of the substrate 20, and are sometimes referred to as the front side redistribution structure and front side interconnects. A structure 100F is obtained, as illustrated in FIG. 1F.

In some embodiments, the fabrication of the IC device 100 further comprises forming various features and/or structures on the back side (e.g., the lower side in FIG. 1F) of the substrate 20. In an example manufacturing process, the structure 100F is flipped over and temporarily bonded to a carrier (not shown). Wafer thinning is performed from the back side (now facing upward) to remove a portion of the substrate 20. For example, as illustrated in FIG. 1F, a substrate portion 130 of the substrate 20 remains as a result of the wafer thinning on the back side. In some embodiments, the wafer thinning process includes a grinding operation, a polishing operation (such as, chemical mechanical polishing (CMP)), or the like. In at least one embodiment, the substrate 20 is completely removed, and a new substrate (not shown), e.g., an insulation substrate, is formed over the bottom semiconductor device 10L. Next, various BMD contacts, BVG vias and BVD vias are formed in manners similar to those correspondingly described with respect to the formation of MD contacts, VG vias and VD vias. A back side redistribution structure is formed, in a manner similar to the redistribution structure 114. The back side redistribution structure comprises various back side metal layers and various back side via layers arranged alternatingly in the thickness direction, i.e., along the Z axis. The back side redistribution structure further comprises various interlayer dielectric (ILD) layers in which the back side metal layers and back side via layers are embedded. The back side metal layer immediately adjacent the bottom semiconductor device 10L is a back side M0 (BM0) layer, a next back side metal layer is a back side M1 (BM1) layer, or the like. A back side via layer BVn is arranged between and electrically couples the BMn layer and the BMn+1 layer, where n is an integer from zero and up. For example, a via layer BV0 is the back side via layer arranged between and electrically couples the BM0 layer and the BM1 layer. Other back side via layers are BV1, BV2, or the like. Conductive patterns in the BM0 layer are referred to as BM0 conductive patterns, conductive patterns in the BM1 layer are referred to as BM1 conductive patterns, or the like. Vias in the BV0 layer are referred to as BV0 vias, vias in the BV1 layer are referred to as BV1 vias, or the like. Although the described manufacturing processes include formation of nanosheet devices in one or more embodiments, other types of devices, e.g., nanowire, FinFET, planar, or the like, are within the scopes of various embodiments. The described manufacturing processes and/or orders of operations are examples. Other manufacturing processes and/or orders of operations are within the scopes of various embodiments.

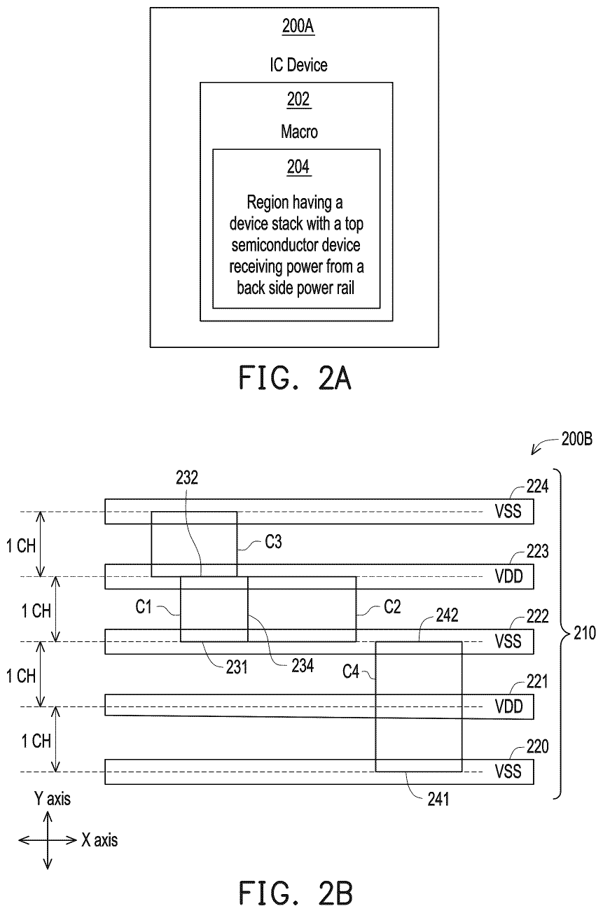

FIG. 2A is a block diagram of an IC device 200A, in accordance with some embodiments.

In FIG. 2A, the IC device 200A comprises, among other things, a macro 202. In some embodiments, the macro 202 comprises one or more of a memory, a power grid, a cell or cells, an inverter, a latch, a buffer and/or any other type of circuit arrangement that may be represented digitally in a cell library. In some embodiments, the macro 202 is understood in the context of an analogy to the architectural hierarchy of modular programming in which subroutines/procedures are called by a main program (or by other subroutines) to carry out a given computational function. In this context, the IC device 200A uses the macro 202 to perform one or more given functions. Accordingly, in this context and in terms of architectural hierarchy, the IC device 200A is analogous to the main program and the macro 202 is analogous to subroutines/procedures. In some embodiments, the macro 202 is a soft macro. In some embodiments, the macro 202 is a hard macro. In some embodiments, the macro 202 is a soft macro which is described digitally in register-transfer level (RTL) code. In some embodiments, synthesis, placement and routing have yet to have been performed on the macro 202 such that the soft macro can be synthesized, placed and routed for a variety of process nodes. In some embodiments, the macro 202 is a hard macro which is described digitally in a binary file format (e.g., Graphic Database System II (GDSII) stream format), where the binary file format represents planar geometric shapes, text labels, other information and the like of one or more layout-diagrams of the macro 202 in hierarchical form. In some embodiments, synthesis, placement and routing have been performed on the macro 202 such that the hard macro is specific to a particular process node.

The macro 202 includes a region 204 which comprises a device stack with a top semiconductor device receiving power from a back side power rail. Examples of a device stack and a top semiconductor device are described with respect to FIG. 1A. Examples of a back side power rail are described herein, e.g., with respect to FIG. 2B. In some embodiments, the region 204 comprises a substrate having circuitry formed thereon, in a front-end-of-line (FEOL) fabrication. Furthermore, above and/or below (e.g., on a front side and/or a back side of) the substrate, the region 204 comprises various metal layers that are stacked over and/or under insulating layers in a Back End of Line (BEOL) fabrication. The BEOL provides a power network and/or routing for circuitry of the IC device 200A, including the macro 202 and the region 204.

FIG. 2B is a schematic view of a layout 200B an IC device, in accordance with some embodiments. In some embodiments, the layout 200B corresponds to the IC device 200A. For simplicity, various features of the layout 200B are omitted in FIG. 2B. In at least one embodiment, the layout 200B is stored on a non-transitory computer-readable recording medium.

The layout 200B comprises a power delivery structure and one or more functional circuits coupled to and powered by power delivered through the power delivery structure. In the example configuration in FIG. 2B, the power delivery structure comprises a power delivery network 210, and the one or more functional circuits are schematically represented by a plurality of cells C1-C4.

The power delivery network 210 comprises a plurality of power rails 220-224 elongated along a first axis (i.e., X axis) and spaced, by a center-to-center interval CH (cell height), from each other along a second axis (Y axis) transverse to the first axis. In at least one embodiment, the Y axis is perpendicular to the X axis. In some embodiments, the power delivery network 210 is a back side power delivery network to be arranged on a back side of an IC device which further includes a front side opposite to the back side in a thickness direction of the IC device. The power rails 220-224 of the power delivery network 210 are configured to provide a first power supply voltage, and a second power supply voltage different from the first power supply voltage. For example, the first power supply voltage is one of VSS and VDD, and the second power supply voltage is the other of VSS and VDD. Power rails configured to provide VSS are sometimes referred to herein as VSS power rails, and power rails configured to provide VDD are sometimes referred to herein as VDD power rails. VDD power rails and VSS power rails are alternatingly arranged along the Y axis. In the example configuration in FIG. 2B, the power rails 220, 222, 224 are VSS power rails which are alternatingly arranged with VDD power rails comprising the power rails 221, 223. In some embodiments, power supply voltages, e.g., VSS and VDD, are provided to the power rails 220-224 through one or more back side metal layers and via layers as described herein.

In some embodiments, the power delivery structure further comprises a front side power delivery network (not shown) on the front side of the IC device. In at least one embodiment, the front side power delivery network comprises one or more power rails extending along the X axis, and arranged in a front side metal layer, as described herein. The power delivery structure further comprises power tap structures or circuits (not shown) configured to deliver VDD and/or VSS from the power delivery network 210 to the front side power delivery network. In some embodiments, the power tap structures are distributed uniformly, or substantially uniformly, across an area of the layout 200B.

The cells C1-C4 correspond to one or more functional circuits of the IC device. The functional circuits are configured to perform one or more functions of the IC device. In some embodiments, the functional circuits comprises one or more active devices, passive devices, logic circuits, or the like. Examples of logic circuits include, but are not limited to, AND, OR, NAND, NOR, XOR, INV, AND-OR-Invert (AOI), OR-AND-Invert (OAI), MUX, Flip-flop, BUFF, Latch, delay, clock, memory, or the like. Example memory cells include, but are not limited to, a static random access memory (SRAM), a dynamic RAM (DRAM), a resistive RAM (RRAIVI), a magnetoresistive RAM (MRAM), a read only memory (ROM), or the like. Examples of active devices or active elements include, but are not limited to, transistors, diodes, or the like. Examples of passive elements include, but are not limited to, capacitors, inductors, fuses, resistors, or the like. In some embodiments, the functional circuits comprise device stacks of semiconductor devices, or CFET devices, as described herein.

The functional circuits are electrically coupled to and powered by the power rails 220-224 and/or one or more power rails of a front side power delivery network. In some embodiments, a front side power delivery network and associated power tap structures are omitted, and the functional circuits of the IC device are coupled to receive power (e.g., VDD and VSS) only from the power delivery network 210 on the back side of the IC device.

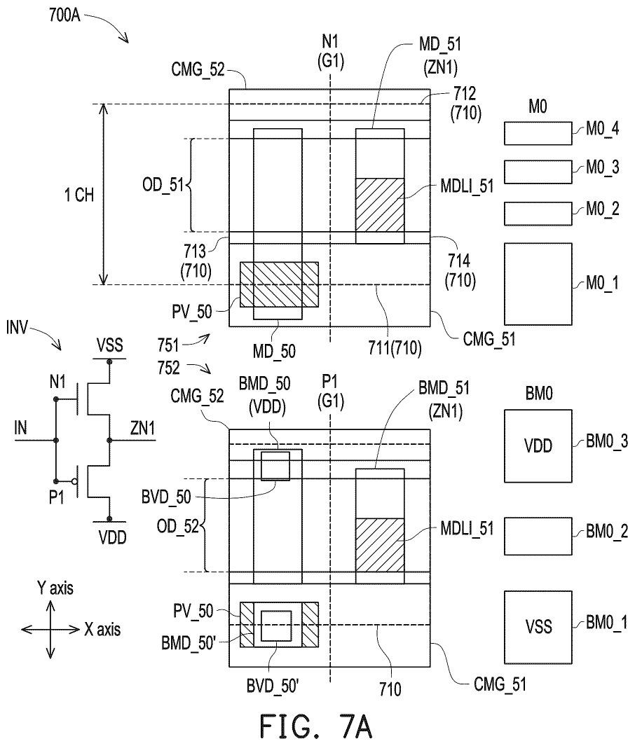

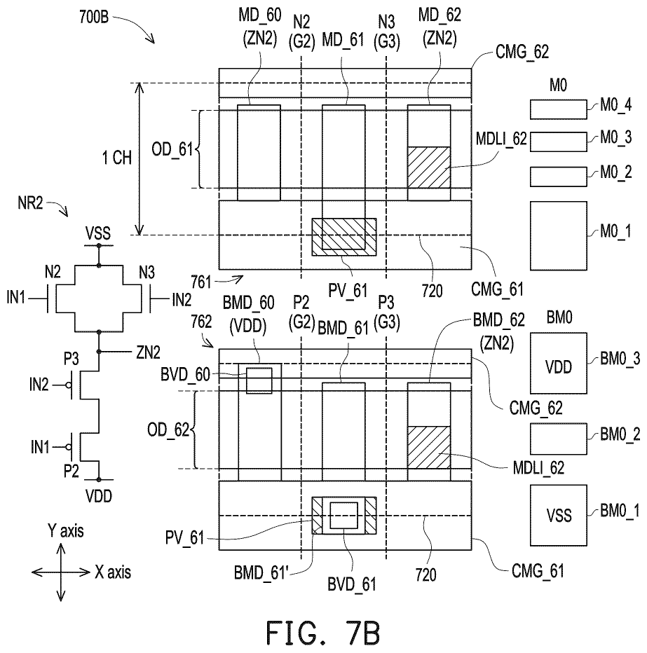

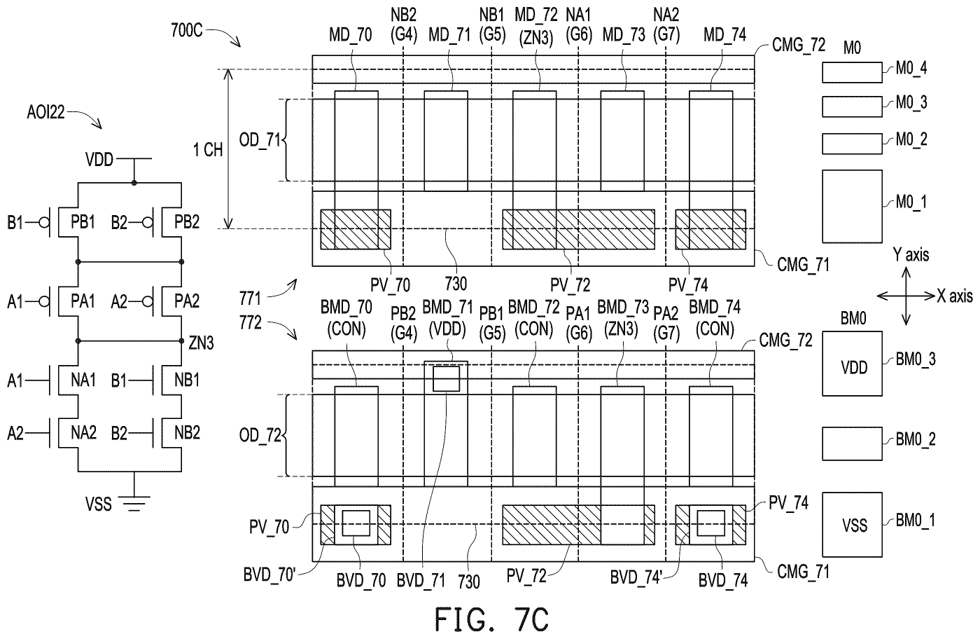

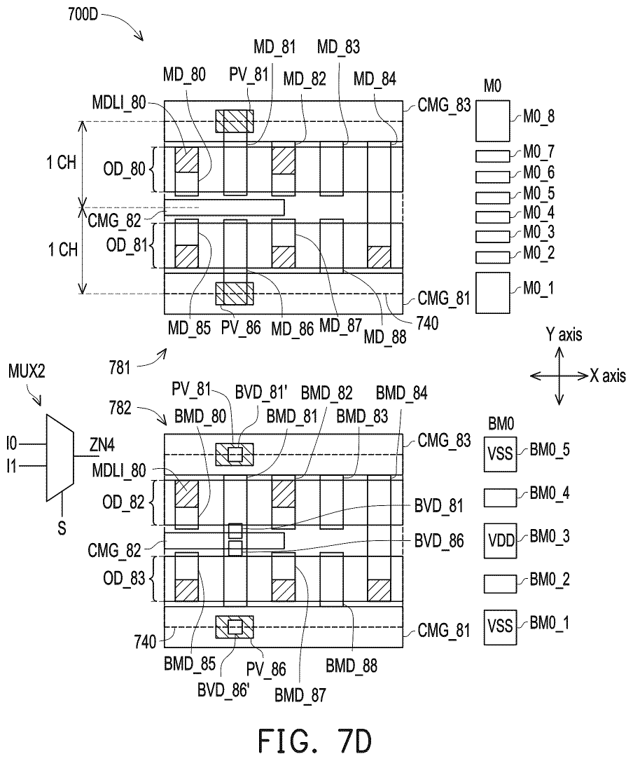

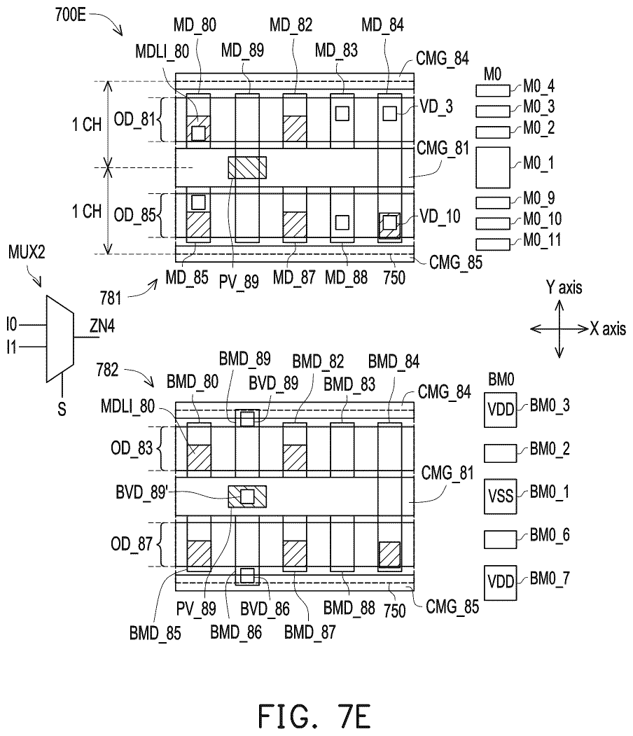

In some embodiments, to generate the layout 200B, various cells, such as the cells C1-C4, are placed, in a placement operation performed by an EDA tool or an automated placement and routing (APR) system, over the power delivery network 210. Non-limiting example cells are described with respect to FIGS. 7A-7E. The cells C1-C4 are schematically represented in FIG. 2B by their corresponding boundaries. One or more cells are placed in the placement operation with their boundaries in abutment with the boundaries of one or more further cells. For example, in the X axis, the cell C1 is placed in abutment with the cell C2 along a common edge 234. In the Y axis, the cell C1 is placed in abutment with the cell C3 along a common edge 232. Cells are not always placed (or placeable) in abutment. For example, the cell C4 is placed to be spaced from the cell C2 along the X axis. The described placement operation is an example. Other placement operations are within the scopes of various embodiments.

A cell is placed over one or more of the power rails 220-224 to receive VDD and/or VSS from the underlying power rails. In some embodiments, a cell is placed with the corresponding boundary over and coinciding with center lines of two power rails. A cell height of the cell along the Y axis corresponds to a center-to-center distance between the two power rails. For example, in FIG. 2B, the boundary of the cell C1 has edges 231, 232 over and coinciding correspondingly with the center lines of the power rails 222, 223. As a result, the cell Cl has a cell height of 1 CH (single cell height) being the center-to-center distance between the power rails 222, 223. The functional circuit in the cell C1 is configured to receive VSS from the power rail 222, and VDD from the power rail 223. For another example, the boundary of the cell C4 has edges 241, 242 over and coinciding correspondingly with the center lines of the power rails 220, 222. As a result, the cell C4 has a cell height of 2 CH (double cell height) being the center-to-center distance between the power rails 220, 222. The cell C4 is further over the power rail 221. The functional circuit in the cell C4 is configured to receive VSS from the power rails 220, 222, and VDD from the power rail 221. The described cells with single cell height or double cell height are examples. Other cells with greater cell heights, e.g., 3 CH, 4 CH, or the like, are within the scopes of various embodiments.

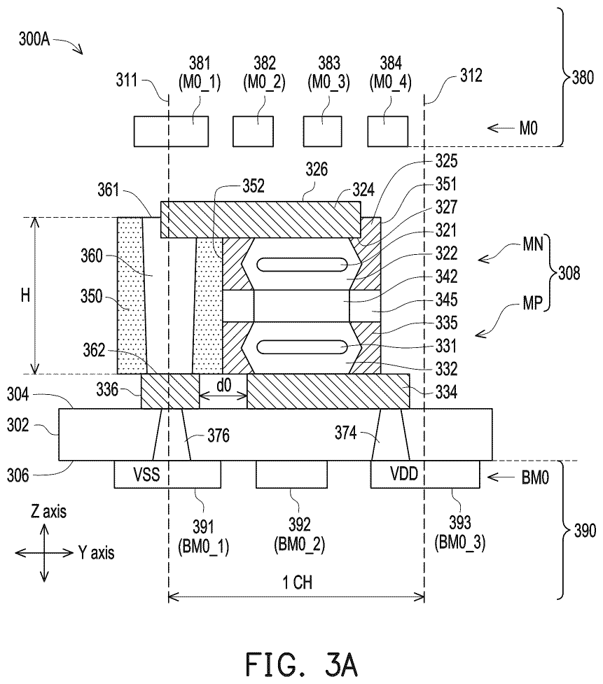

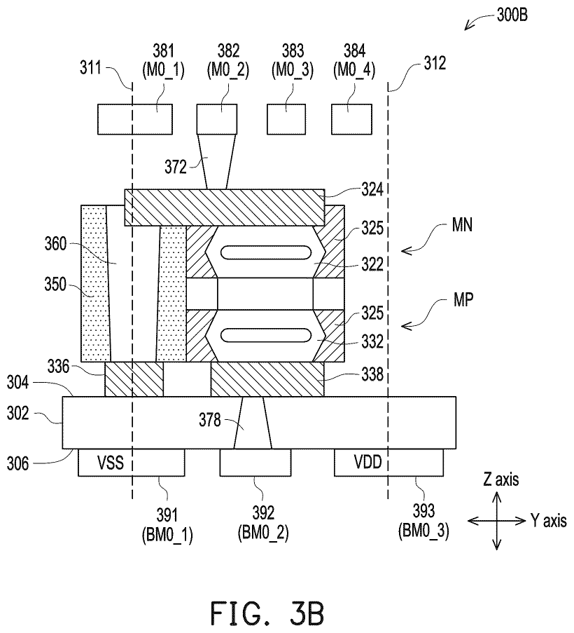

FIG. 3A is a schematic cross-sectional view of a circuit region of an IC device 300A, in accordance with some embodiments. In some embodiments, the IC device 300A corresponds to one or more of the IC device 200A and the layout 200B. In at least one embodiment, FIG. 3A corresponds to a cross-sectional view taken along the Y axis across a cell, e.g., the cell C1, in FIG. 2B.

As illustrated in FIG. 3A, the IC device 300A comprises a substrate 302 having a front side 304, and a back side 306 opposite to the front side 304 in a thickness direction, i.e., Z axis, of the substrate 302. In some embodiments, the substrate 302 comprises a semiconductor material, such as silicon, silicon germanium (SiGe), gallium arsenic, or other suitable semiconductor materials. In some embodiments, the substrate 302 comprises a dielectric material, such as silicon nitride, silicon oxide, ceramic, glass, or other suitable materials. In some embodiments, the substrate 302 comprises a multi-layer structure. In some embodiments, the substrate 302 is omitted, or comprises an insulation layer that replaces an initial semiconductor bulk used during manufacture. In at least one embodiment, the substrate 302 corresponds to one or more substrates described with respect to FIGS. 1A-1F.

The IC device 300A further comprises a device stack 308 comprising a bottom semiconductor device MP, and a top semiconductor device MN stacked over the bottom semiconductor device MP along the thickness direction, i.e., the Z axis. In some embodiments, the device stack 308 corresponds to the device stack 100A, and/or is manufactured by one or more processes or operations described with respect to FIGS. 1B-1F. The device stack 308 is configured over the front side 304 of the substrate 302.

In the example configuration in FIG. 3A, the top semiconductor device MN is an N-type semiconductor device and the bottom semiconductor device MP is a P-type semiconductor device, which together configure the device stack 308 as a CFET device. Each of the top semiconductor device and bottom semiconductor device comprises a channel which is arranged in a corresponding active region. For example, a channel 321 of the top semiconductor device MN comprises a semiconductor material, such as Si, in a corresponding top active region (not numbered), and is configured as an N-type nanosheet. In some embodiments, the channel 321 comprises multiple N-type nanosheets stacked over, while being spaced from, each other in the thickness direction. Similarly, a channel 331 of the bottom semiconductor device MP comprises a semiconductor material, such as Si, in a corresponding bottom active region (not numbered) below the top active region, and is configured as a P-type nanosheet. In some embodiments, the channel 331 comprises multiple P-type nanosheets stacked over, while being spaced from, each other in the thickness direction. The described channel material and nanosheets are examples. Other channel materials and/or channel types, such as nanowire, FinFET, planar, or the like, are within the scopes of various embodiments.

Each of the top semiconductor device and bottom semiconductor device further comprises a gate. For example, the top semiconductor device MN comprises a gate 325 which is an all-around gate extending around the channel 321, and the bottom semiconductor device MP comprises a gate 335 which is an all-around gate extending around the channel 331. In the example configuration in FIG. 3A, the gates 325, 335 are electrically isolated from each other by a dielectric layer 345 in an isolated gate configuration as described herein. In at least one embodiment, the gates 325, 335 are electrically coupled to each other by a conductor, e.g., a gate local interconnect (MGLI) (not shown). In some embodiments, the gates 325, 335 are metal gates. Other gate materials, such as polysilicon, are within the scopes of various embodiments. In some embodiments, the gate material of the gate 325 and/or the gate 335 replaces a sacrificial material, such as SiGe, in the corresponding active region during a manufacturing process.

Each top semiconductor device or bottom semiconductor device further comprises a gate dielectric (not shown) between the corresponding gate and channel. For example, a gate dielectric is between each of the gate 325 and the corresponding channel 321, and extends around the channel 321. Example materials of the gate dielectric include high-k dielectric materials, or the like.

Each top semiconductor device further comprises source/drains (sometimes referred to as top source/drains) in the corresponding top active region, and each bottom semiconductor device further comprises source/drains (sometimes referred to as bottom source/drains) in the corresponding bottom active region. For example, the top semiconductor device MN includes a source/drain 322, and the bottom semiconductor device MP includes a source/drain 332. The other source/drain of the top semiconductor device MN and the other source/drain of the bottom semiconductor device MP are not visible/shown in FIG. 3A. In some embodiments, source/drains of a semiconductor device are coupled to the corresponding channel, and are arranged in the same active region as a the channel. For example, the source/drain 322 and the other source/drain (not shown) of the top semiconductor device MN are coupled by the channel 321, and are all in the top active region containing the channel 321. For another example, the source/drain 332 and the other source/drain (not shown) of the bottom semiconductor device MP are coupled by the channel 331, and are all in the bottom active region containing the channel 331.

In the example configuration in FIG. 3A, the IC device 300A further comprises a source/drain local interconnect (MDLI) 342 arranged between and electrically coupling the source/drains 322, 332. In some embodiments, the MDLI interconnect 342 is omitted, i.e., replaced by a dielectric material, to electrically isolate the source/drains 322, 332. In at least one embodiment, an MDLI interconnect other than the MDLI interconnect 342 is provided between and electrically couples the source/drains 322, 332. An example material of MDLI interconnects comprises a metal.

The IC device 300A further comprises MD contacts for the top semiconductor device MN, and BMD contacts for the bottom semiconductor device MP. For example, an MD contact 324, i.e., a top contact structure, is over and in electrical contact with the source/drain 322 of the top semiconductor device MN, whereas a BMD contact 334, i.e., a bottom contact structure, is under and in electrical contact with the source/drain 332 of the bottom semiconductor device MP. An MD contact (not shown) similar to the MD contact 324 is over and in electrical contact with the other source/drain of the top semiconductor device MN. A BMD contact (not shown) similar to the BMD contact 334 is under and in electrical contact with the other source/drain of the bottom semiconductor device MP.

The IC device 300A further comprises a conductor 336 co-elevational with the BMD contact 334 along the Z axis, and spaced from the BMD contact 334 along the Y axis. In some embodiments, a first element is co-elevational with a second element when at least one portion of the first element and at least one portion of the second element are in a plane perpendicular to the Z axis. In at least one embodiment, an entirety of the conductor 336 is co-elevational with an entirety of the BMD contact 334. In some embodiments, the conductor 336 comprises the same material as the BMD contact 334. In some embodiments, the conductor 336 is formed simultaneously with the BMD contact 334, from the same material, in the same manufacturing process, using the same mask. In other words, the conductor 336 is a bottom contact structure like the BMD contact 334, with the exception that the conductor 336 does not overlap and is not in contact with a source/drain or an active region. In at least one embodiment, a spacing d0 between the BMD contact 334 and the conductor 336 along the Y axis is equal to or greater than a predetermined spacing, i.e., a design rule, for ensuring that the IC device 300A is manufacturable.

The IC device 300A further comprises a dielectric structure 350 in contact with the gates 325, 335 along a surface 352. In some embodiments, the dielectric structure 350 corresponds to a cut-metal-gate (CMG) mask, or a cut-poly (silicon) (CPO) mask, or a similar cut-gate mask configured to define or configure the length of one or more gates. For simplicity, CMG, CPO and cut-gate are used interchangeably herein to designate such a gate length defining mask. The IC device 300A further comprises a further dielectric structure (not shown for simplicity) similar to the dielectric structure 350, but on the other side of the gates 325, 335 along the Y axis, and in contact with the gates 325, 335 along a surface 351 opposite to the surface 352. The length of the gates 325, 335 is defined or configured by a distance along the Y axis between the dielectric structure 350 and the further dielectric structure. In the example configuration in FIG. 3A, the dielectric structure 350 and the further dielectric structure have corresponding center lines 311, 312. In some embodiments, the center lines 311, 312 correspond to center lines of corresponding power rails and/or edges of a boundary of a cell, as described with respect to FIG. 2B.

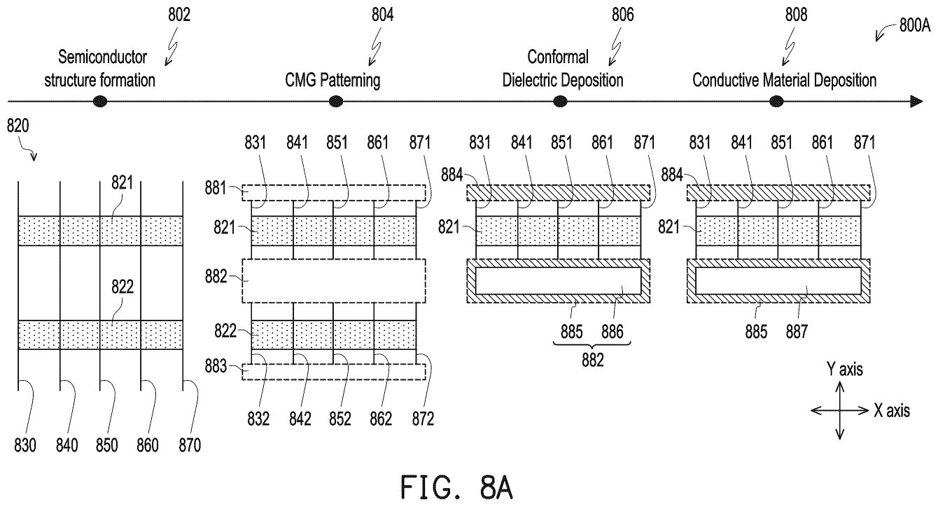

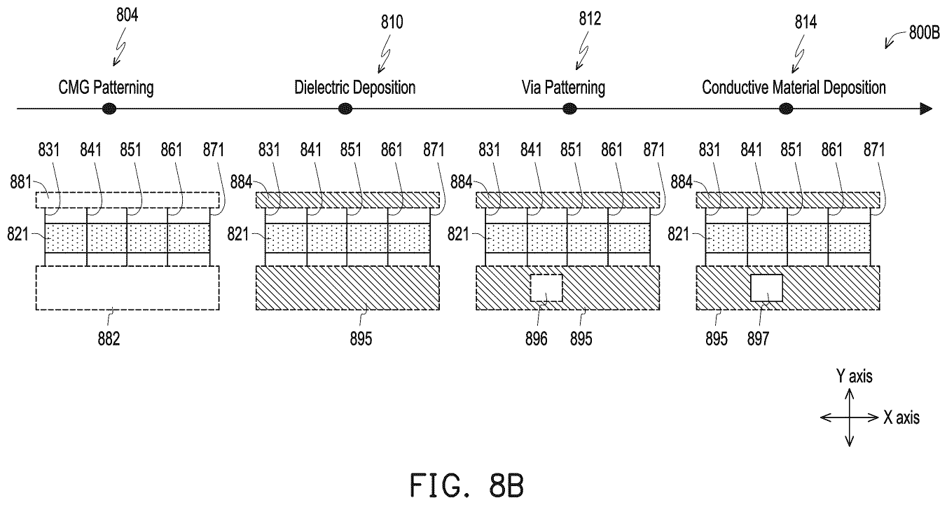

The IC device 300A further comprises a via interconnect 360 extending between and electrically coupling the MD contact 324 and the conductor 336. The via interconnect 360 is embedded in and surrounded by the dielectric structure 350. The dielectric structure 350 and the via interconnect 360 are co-elevational with the gates 325, 335. In at least one embodiment, an entirety of the gate 325 and/or an entirety of the gate 335 is/are co-elevational with the dielectric structure 350 and/or the via interconnect 360. The via interconnect 360 electrically isolates the via interconnect 360 from the gates 325, 335. In some embodiments, the via interconnect 360 is formed using the same CMG mask used to form the dielectric structure 350, and is therefore referred to as a self-aligned via interconnect 360. An example process in accordance with some embodiments is described with respect to FIG. 8A. In at least one embodiment, the via interconnect 360 is formed using a separate mask in addition to the CMG mask used to form the dielectric structure 350. An example process in accordance with some embodiments is described with respect to FIG. 8B.

A top portion of the via interconnect 360 is electrically coupled to the MD contact 324. In the example configuration in FIG. 3A, the MD contact 324 extends along the Y axis into the top portion of the via interconnect 360, such that a top surface 361 of the via interconnect 360 is, along the Z axis, between a top surface 326 and a bottom surface 327 of the MD contact 324. Other configurations are within the scopes of various embodiments. For example, in one or more embodiments, the top surface 326 of the MD contact 324 is flush with or below the top surface 361 of the via interconnect 360. A bottom portion of the via interconnect 360 is electrically coupled to the conductor 336. In the example configuration in FIG. 3A, a bottom surface 362 of the via interconnect 360 is over and in contact with a top surface of the conductor 336. Other configurations are within the scopes of various embodiments. In some embodiments, the via interconnect 360 has a center line coinciding, or aligned, with the center line 311.

In some embodiments, the IC device 300A further comprises at least one of a VG via (not shown) over and in electrical contact with the gate 325, or a BVG via (not shown) under and in electrical contact with the gate 335. In at least one embodiment, the IC device 300A further comprises at least one VD via (not shown) over and in electrical contact with the other source/drain of the top semiconductor device MN, or at least one BVD via under and in electrical contact with at least one of the BMD contacts of the bottom semiconductor device MP. In the example configuration in FIG. 3A, the IC device 300A comprises a BVD via 374 under and in electrical contact with the BMD contact 334. Specifically, the BVD via 374 extends from the back side 306, through the substrate 302, to the front side 304 where the BVD via 374 comes into contact with the BMD contact 334.

The IC device 300A further comprises a via 376 under and in electrical contact with the conductor 336. Specifically, the via 376 extends from the back side 306, through the substrate 302, to the front side 304 where the via 376 comes into contact with the conductor 336. In some embodiments, the via 376 comprises the same material as the BVD via 374. In some embodiments, the via 376 is formed simultaneously with the BVD via 374, from the same material, in the same manufacturing process, using the same mask. In other words, the via 376 is a BVD via like the BVD via 374, with the exception that the via 376 is in contact with the conductor 336 rather than with a BMD contact. The via 376 and similar vias electrically coupled to conductors like the conductor 336 are sometimes referred to herein as BVD vias.

The IC device 300A further comprises a front side redistribution structure 380, and a back side redistribution structure 390. The redistribution structure 380 is on the front side, over the VD, VG vias, and comprises a plurality of metal layers and via layers sequentially and alternatingly arranged over the VD, VG vias, as described herein with respect to FIG. 1F. The back side redistribution structure 390 is on the back side, and similarly comprises a plurality of metal layers and via layers sequentially and alternatingly arranged under the BVD, BVG vias. A metal layer, i.e., M0 layer, of the front side redistribution structure 380 and a metal layer, i.e., BM0 layer, of the back side redistribution structure 390 are illustrated in FIG. 3A, whereas other layers and/or features of the front side redistribution structure 380 and back side redistribution structure 390 are omitted for simplicity. Among the metal layers of the front side redistribution structure 380, the M0 layer is the metal layer closest to the device stack 308. Among the metal layers of the back side redistribution structure 390, the BM0 layer is the metal layer closest to the device stack 308.

In the example configuration in FIG. 3A, the M0 layer comprises, over the device stack 308, metal patterns 381-384 correspondingly on M0 tracks M0_1-M0_4. In some embodiments, one or more of the metal patterns 381-384 is/are omitted. The tracks M0_1-M0_4 are elongated along the X axis (FIG. 2B), and are arranged side by side along the Y axis. Specifically, the track M0_1 is immediately adjacent to the track M0_2, which is immediately adjacent to the track M0_3, which is immediately adjacent to the track M0_4. Two M0 tracks are considered directly adjacent (or immediately adjacent) where there are no other M0 tracks therebetween. M0 metal patterns on immediately adjacent M0 tracks are considered immediately adjacent. For example, along the Y axis, the metal pattern 381 is immediately adjacent to the metal pattern 382. Along the Y axis, the metal pattern 381 on the track M0_1 has a width greater than a width of each of the metal patterns 382-384 on the tracks M0_2-M0_4.

The metal pattern 381 extends across the center line 311 and is configured to be shared with another device stack (not shown) on the left side of the device stack 308 in FIG. 3A. In some embodiments, the metal pattern 381 has a center line coinciding, or aligned, with the center line 311. In some embodiments, the metal pattern 381 comprises a power rail similar to one or more power rails described with respect to FIG. 2B, but belonging to a front side power delivery network. For example, the metal pattern 381 is configured in one or more embodiments as a VSS power rail to provide VSS to one or more N-type top semiconductor devices in one or more device stacks of the IC device 300A. In at least one embodiment, because power for N-type top semiconductor devices, such as the top semiconductor device MN, is delivered from the back side, e.g., through the via interconnect 360 as described herein, the metal pattern 381 is configured for other purposes, e.g., for signals. For example, in one or more embodiments, a double cell height (2 CH) cell comprises two single cell height (1 CH) structures which are symmetrical across the center line 311, and one of which is the 1 CH structure between the center lines 311, 312 in FIG. 3A. In such a 2 CH cell, the metal pattern 381 is shared between the two 1 CH structures, and is configured as an internal signal pattern of the 2 CH cell.

The metal patterns 382-384 on the tracks M0_2-M0_4 are arranged between the center lines 311, 312. In some embodiments, the metal patterns 382-384 are configured to transmit signals between the device stack 308 and other device stacks or CFET devices in the IC device 300A. The metal patterns 382-384 and the tracks M0_2-M0_4 are sometimes referred correspondingly to as M0 signal patterns and M0 signal tracks. For example, at least one of the metal patterns 382-384 is electrically coupled to the gate 325 or a source/drain of the top semiconductor device MN through a corresponding VG via or VD via. In some embodiments, at least one of the metal patterns 382-384 is electrically coupled to the gate 335 or a source/drain of the bottom semiconductor device MP through a via or local interconnect (not shown) extending between the M0 layer and the gate 335 or the source/drain of the bottom semiconductor device MP. The described number of three M0 signal tracks between the center lines 311, 312 (i.e., over 1 CH) is an example. Other numbers of M0 signal tracks over 1 CH are within the scopes of various embodiments.

In the example configuration in FIG. 3A, the BM0 layer comprises, under the device stack 308 and on the back side 306 of the substrate 302, metal patterns 391-393 correspondingly on BM0 tracks BM0_1-BM0_3. The tracks BM0_1-BM0_3 are elongated along the X axis, and are arranged side by side along the Y axis. Specifically, the track BM0_1 is immediately adjacent to the track BM0_2, which is immediately adjacent to the track BM0_3. Two BM0 tracks are considered directly adjacent (or immediately adjacent) where there are no other BM0 tracks therebetween. BM0 metal patterns on immediately adjacent BM0 tracks are considered immediately adjacent. For example, along the Y axis, the metal pattern 391 is immediately adjacent to the metal pattern 392. Along the Y axis, the metal patterns 391, 393 on the tracks BM0_1, BM0_3 has a width greater than a width of the metal pattern 392 on the track BM0_2.

The metal pattern 391 extends across the center line 311 and is configured to be shared with another device stack (not shown) on the left side of the device stack 308 in FIG. 3A. In some embodiments, the metal pattern 391 has a center line coinciding, or aligned, with the center line 311. The metal pattern 393 extends across the center line 312 and is configured to be shared with another device stack (not shown) on the right side of the device stack 308 in FIG. 3A. In some embodiments, the metal pattern 393 has a center line coinciding, or aligned, with the center line 312. The metal patterns 391, 393 are configured as back side power rails of a back side power delivery network described with respect to FIG. 2B. In the example configuration in FIG. 3A, the metal pattern 391 is a VSS power rail configured to provide VSS to the top semiconductor device MN and corresponding to one or more of the VSS power rails 220, 222, 224 whereas the metal pattern 393 is a VDD power rail configured to provide VDD to the bottom semiconductor device MP and corresponding to one or more of the VDD power rails 221, 223 in FIG. 2B. The BM0 tracks BM0_1, BM0_3 are sometimes referred to as BM0 power tracks.

The metal pattern 392 on the track BM0_2 is arranged between the center lines 311, 312. In some embodiments, the metal pattern 392 is configured to transmit signals between the device stack 308 and other device stacks, or CFET devices, in the IC device 300A. The metal pattern 392 and the track BM0_2 is sometimes referred correspondingly to as a BM0 signal pattern and a BM0 signal track. For example, the metal pattern 392 is electrically coupled to the gate 335 or a source/drain of the bottom semiconductor device MP through a corresponding BVG via or BVD via. In some embodiments, the metal pattern 392 is electrically coupled to the gate 325 or a source/drain of the top semiconductor device MN through a via or local interconnect (not shown) extending between the BM0 layer and the gate 325 or the source/drain of the top semiconductor device MN. The described number of one BM0 signal track between the center lines 311, 312 (i.e., over 1 CH) is an example. Other numbers of BM0 signal tracks over 1 CH are within the scopes of various embodiments. In some embodiments, the metal pattern 392 and/or the track BM0_2 is/are omitted.

The metal pattern 393, referred to herein as power rail 393, is in electrical contact with the BVD via 374. As a result, VDD on the power rail 393 is provided to the source/drain 332 of the bottom semiconductor device MP through the BVD via 374 and BMD contact 334. In some embodiments, the BVD via 374 is omitted, e.g., when the bottom semiconductor device MP is not directly powered by VDD.

The metal pattern 391, referred to herein as power rail 391, is in electrical contact with the BVD via 376, and is electrically coupled to the via interconnect 360 through the BVD via 376. As a result, VSS on the power rail 391 is provided to the source/drain 322 of the top semiconductor device MN through an electrical connection comprising the BVD via 376, conductor 336, via interconnect 360, and MD contact 324. The top semiconductor device MN receives power (i.e., VSS) from the back side power delivery network, rather than from a front side power delivery network. An entirety of the electrical connection from the power rail 391 to the source/drain 322, i.e., the BVD via 376, conductor 336, via interconnect 360 and MD contact 324, is below the M0 layer, i.e., below the metal layers of the front side redistribution structure 380. In the example configuration in FIG. 3A, the power rail 391 overlaps, along the Z axis, an entirety of at least one of the BVD via 376, the conductor 336, the via interconnect 360, or the metal pattern 381.

As described herein, because the top semiconductor device MN receives power (e.g., VSS) from the back side power delivery network through the via interconnect 360, it is no longer necessary to provide power (e.g., VSS) to the top semiconductor device MN from a front side power delivery network, i.e., from one or more metal layers of the front side redistribution structure 380. In some embodiments, it is possible to configure the IC device 300A to be free of a front side power delivery network. In at least one embodiment, the M0 layer in the IC device 300A is configured to be free of a power rail directly over the via interconnect 360, i.e., the metal pattern 381 is not a power rail. Because a front side power delivery network for powering top semiconductor devices are not required in one or more embodiments, power tap structures for delivery power from the back side power delivery network to a front side power delivery network are also not required. In at least one embodiment, the IC device 300A is free of power tap structures. As a result, it is possible in one or more embodiments to simplify the IC design and/or fabrication, free up front side metal layers for purposes other than power delivery, while saving a chip area that would otherwise be configured as a power tap area for power tap structures.

In some embodiments, one or more circuit regions of the IC device 300A still require a front side power delivery network for design-and/or operation-related reasons. In such embodiments, IC device 300A includes one or more power tap structures. However, the required amount of power tap structures and/or power tap area is still reduced compared to other approaches where top semiconductor devices of CFET devices are powered from a front side power delivery network. Additionally or alternatively, it is possible in one or more embodiments to ensure that a voltage drop (or IR drop) in the power delivery structure for the IC device 300A is within a predetermined or acceptable range. One or more further advantages are achievable in various embodiments, as described herein.

The described configuration for power delivery to an N-type top semiconductor device in a device stack is an example. Other configurations are within the scopes of various embodiments. For example, in some embodiments where the device stack 308 comprises a P-type top semiconductor device over an N-type bottom semiconductor device, the power rails 391, 393 are configured correspondingly as a VDD power rail and a VSS power rail, and VDD is provided from the power rail 391 through the electrical connection including the via interconnect 360 to the P-type top semiconductor device. One or more advantages described herein with respect to a device stack, or CFET device, comprising an N-type top semiconductor device over a P-type bottom semiconductor device are also achievable in a device stack, or CFET device, comprising a P-type top semiconductor device over an N-type bottom semiconductor device.

The IC device 300A is an example of configuring a via interconnect embedded in a gate length defining dielectric structure for power delivery. In some embodiments, such a via interconnect is configured instead for signals, e.g., data, control, clock, or the like.

FIG. 3B is a schematic cross-sectional view, similar to FIG. 3A, of a circuit region of an IC device 300B, in accordance with some embodiments. In some embodiments, the IC device 300B corresponds to one or more of the IC device 200A and the layout 200B. In at least one embodiment, the IC device 300B corresponds to the IC device 300A or a portion of the IC device 300A. Components in FIG. 3B having corresponding components in FIG. 3A are designated by the same reference numerals as in FIG. 3A.

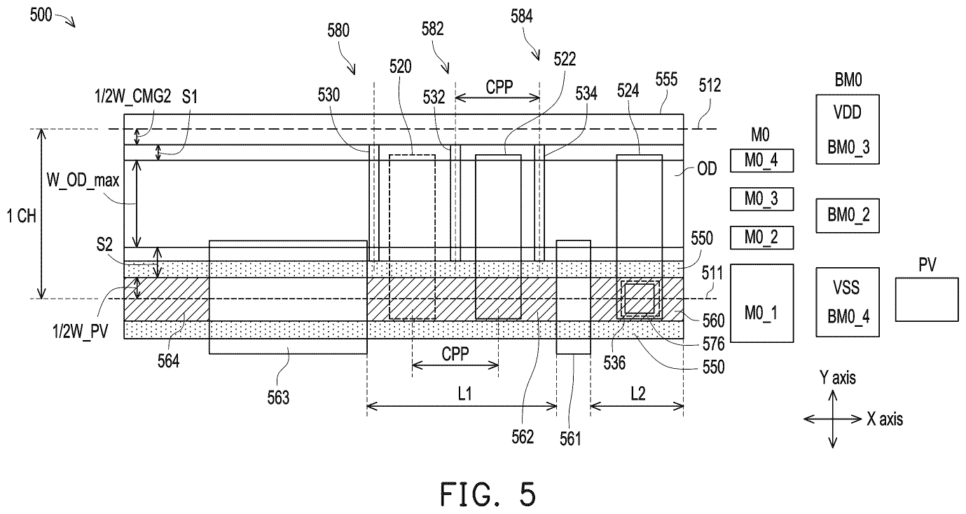

Compared to the IC device 300A in which the via interconnect 360 is configured for power delivery from the back side power delivery network to the top semiconductor device, the via interconnect 360 in the IC device 300B is configured for signal transmission to/from the top semiconductor device. Specifically, the BVD via 376 is omitted, and the conductor 336 is not electrically coupled to the power rail 391. Instead, the conductor 336 extends along the X axis to be electrically coupled to a BMD contact of a further bottom source/drain (not shown) other than the source/drain 322. As a result, the source/drain 322 of the top semiconductor device MN is electrically coupled to the further bottom source/drain through the MD contact 324, the via interconnect 360, the conductor 336 and the BMD contact of the further bottom source/drain. In some embodiments, the further bottom source/drain is the other source/drain of the bottom semiconductor device MP. In at least one embodiment, the further bottom source/drain is a source/drain of a bottom semiconductor device of another CFET device. Example configurations of the conductor 336 for signal transmission are described with respect to FIGS. 5, 6, 7C.

The IC device 300B further comprises a VD via 372 electrically coupling the MD contact 324 to the metal pattern 382. In some embodiments, the VD via 372 is omitted.

In the example configuration in FIG. 3B, the source/drain 332 is not directly powered by VDD, and the BVD via 374 is omitted. The IC device 300B comprises a BMD contact 338 shorter than, and instead of, the BMD contact 334. The BMD contact 338 is under and in electrical contact with the source/drain 332. The IC device 300B further comprises a BVD via 378 electrically coupling the BMD contact 338 to the metal pattern 392 for signal transmission to/from the source/drain 332. In some embodiments, the BVD via 378 is omitted. In at least one embodiment, the source/drain 322 is coupled to receive VDD by the BMD contact 334 and BVD via 374 which correspondingly replace the BMD contact 338 and BVD via 378. The BMD contact 334 is an example of a BMD contact for power delivery, and the BMD contact 338 is an example of a BMD contact for signal transmission.

As described herein, it is possible in one or more embodiments, to configure a via interconnect embedded in a gate length defining dielectric structure either for power delivery (e.g., as in the IC device 300A) or for signal transmission (e.g., as in the IC device 300B). In either case, one or more metal patterns, e.g., in the M0 layer, which would be required for power delivery or for signal transmission in other approaches, are freed up and are usable for routing to other circuit elements. As a result, it is possible in one or more embodiments to achieve one or more advantages including, but not limited to, improved routing efficiency, simplified routing tasks, reduced crowdedness of signal patterns with one or more further associated advantages such as reduced time delays, faster/higher performance, or the like. One or more further advantages described herein are achievable by one or more of the IC devices 300A, 300B, in accordance with some embodiments.

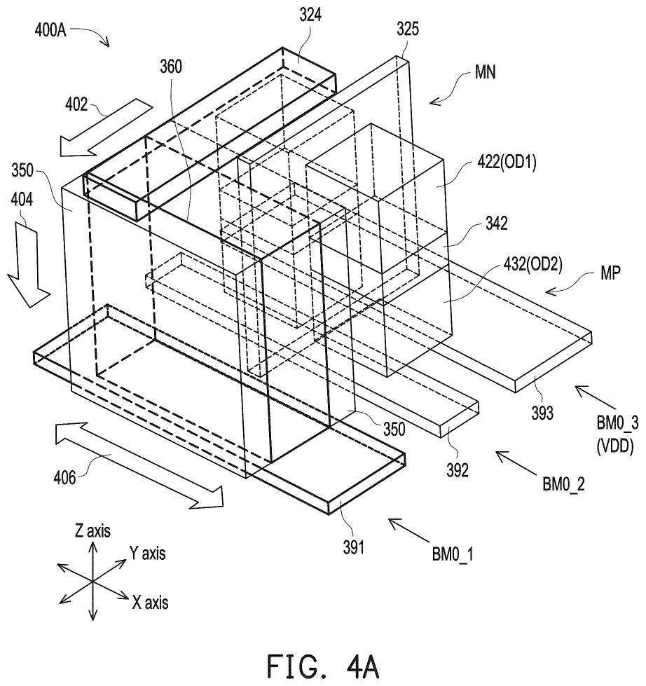

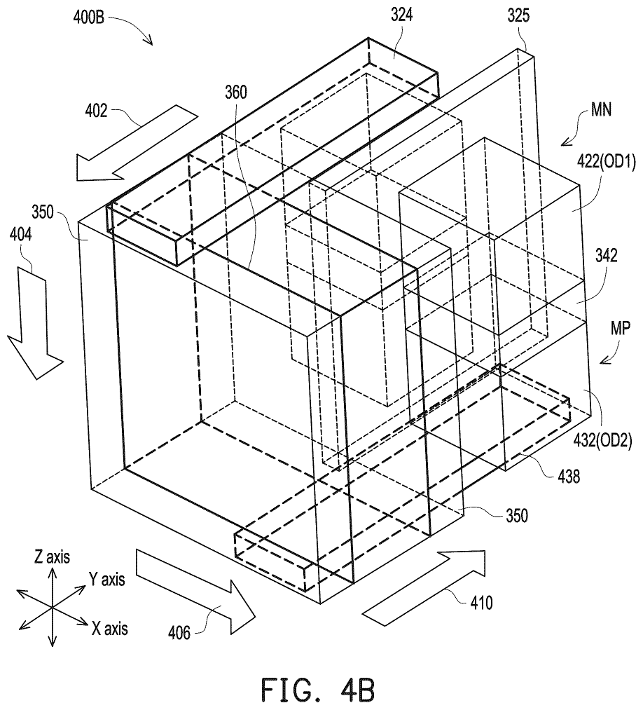

FIG. 4A is a schematic perspective view of a circuit region of an IC device 400A, in accordance with some embodiments. In some embodiments, the IC device 400A corresponds to the IC device 300A. Components in FIG. 4A having corresponding components in FIGS. 3A, 3B are designated by the same reference numerals as in FIGS. 3A, 3B.

In FIG. 4A, the other source/drains of the top semiconductor device MN and bottom semiconductor device MP, which are not visible in FIG. 3A, are shown. Specifically, the top semiconductor device MN comprises a source/drain 422 which, together with the source/drain 322 (below the MD contact 324 in FIG. 4A) and the channel 321 (not shown in FIG. 4A), belongs to a top active region OD1. The bottom semiconductor device MP comprises a source/drain 432 which, together with the source/drain 332 (not shown in FIG. 4A) and the channel 331 (not shown in FIG. 4A), belongs to a bottom active region OD2. For simplicity, various features, such as, the conductor 336, BVD via 376, an MD contact over the source/drain 422, a BMD contact under the source/drain 432, or the like, are not illustrated in FIG. 4A. FIG. 4A includes arrows 402, 404, 406 schematically showing a connection from the source/drain 322 (not shown in FIG. 4A) through the MD contact 324 and the via interconnect 360 to the power rail 391 along which VSS is delivered.

FIG. 4B is a schematic perspective view of a circuit region of an IC device 400B, in accordance with some embodiments. In some embodiments, the IC device 400B corresponds to the IC device 300B. Components in FIG. 4B having corresponding components in FIGS. 3A, 3B, 4A are designated by the same reference numerals as in FIGS. 3A, 3B, 4A.

In FIG. 4B, the IC device 400B comprises a BMD contact 438 for signal transmission under the source/drain 432. For simplicity, various features, such as, the conductor 336, an MD contact over the source/drain 422, the metal patterns 391-393, or the like, are not illustrated in FIG. 4B. FIG. 4B includes arrows 402, 404, 406, 410 schematically showing a connection from the source/drain 322 (not shown in FIG. 4B) through the MD contact 324, the via interconnect 360 and the BMD contact 438 to the source/drain 432 which is not directly under the source/drain 322. The configuration described with respect to FIG. 4B is an example of configuring the via interconnect 360 for signal transmission between non-overlapping source/drains of the top semiconductor device and the bottom semiconductor device in the same device stack, or CFET device. Other configurations, in which the via interconnect 360 or a similar via interconnect is configured for signal transmission between non-overlapping source/drains of a top semiconductor device and a bottom semiconductor device in different device stacks or CFET devices, are within the scopes of various embodiments. One or more advantages described herein are achievable by one or more of the IC devices 400A, 400B.

FIG. 5 is a schematic view of a layout 500 of a circuit region of an IC device, in accordance with some embodiments. In some embodiments, the layout 500 corresponds to one or more of the IC devices 200A, 300A, 300B, 400A, 400B, or to the layout 200B. In at least one embodiment, the layout 500 is stored on a non-transitory computer-readable recording medium. Components in FIG. 5 having corresponding components in FIGS. 2B, 3A, 3B, 4A, 4B are designated by the same reference numerals as in FIGS. 2B, 3A, 3B, 4A, 4B.

The layout 500 comprises a plurality of CFET devices arranged along a first axis, e.g., the X axis. Specifically, the layout 500 comprises an active region OD elongated along the X axis, and a plurality of gate regions extending along the Y axis across the active region OD. The active region OD and each of the gate regions configure a corresponding CFET device. For example, gate regions 530, 532, 534 are illustrated in FIG. 5, whereas other gate regions are not shown for simplicity. The active region OD and the gate regions 530, 532, 534 correspondingly configure CFET devices 580, 582, 584. The active region OD schematically presents both a top active region for top semiconductor devices of the CFET devices, and a bottom active region for bottom semiconductor devices of the CFET devices. In some embodiments, the active region OD comprises the top active region OD1 and bottom active region OD2 described herein. Each of the gate regions 530, 532, 534 schematically presents both a gate or gate region of the top semiconductor device, and a gate or gate region of the bottom semiconductor device of the corresponding CFET device. In some embodiments, each of the gate regions 530, 532, 534 corresponds to both the gates 325, 335. In some embodiments, each of the CFET devices 580, 582, 584 corresponds to the device stack 308.

The gate regions 530, 532, 534 are arranged along the X axis at a regular pitch designated at CPP (contacted poly pitch) in FIG. 5. CPP is a center-to-center distance along the X axis between two directly adjacent gate regions. Two gate regions are considered directly adjacent (or immediately adjacent) where there are no other gate regions therebetween. CFET devices corresponding to immediately adjacent gate regions are considered as immediately adjacent CFET devices. Some gate regions in the layout 500 are functional gate regions which, together with the active region OD, configure semiconductor devices or transistors coupled into circuitry configured to perform a predetermined operation or function. In at least one embodiment, some other gate regions of the layout 500 are non-functional, or dummy, gate regions. Dummy gate regions are not configured to form transistors together with the active region OD, and/or one or more transistors formed by dummy gate regions together with the active region OD are not electrically coupled to other circuitry. In at least one embodiment, non-functional or dummy gates corresponding to dummy gate regions include dielectric material in a manufactured IC device corresponding to the layout 500. Other configurations are within the scopes of various embodiments.

The length of each of the gate regions in the layout 500 is defined or configured by a pair of CMG regions of a CMG mask. For example, the length of each of the gate regions 530, 532, 534 is defined by and between CMG regions 550, 555. In some embodiments, the CMG region 550 corresponds to the dielectric structure 350 in a manufactured IC device corresponding to the layout 500, whereas the CMG region 555 corresponds to the further dielectric structure described with respect to FIG. 3A. In some embodiments, each of the CMG regions 550, 555 and the corresponding dielectric structures has a constant width in the Y axis over an entire length of the CMG region or dielectric structure along the X axis. The CMG regions 550, 555 have corresponding center lines 511, 512 spaced from each other along the Y axis by 1 CH. In some embodiments, the center lines 511, 512 correspond to the center lines 311, 312, and/or center lines of power rails and/or edges of a boundary of a cell, as described with respect to FIG. 2B. In some embodiments, gate regions in the layout 500 have different lengths. For example, in a region (not shown) where the CMG region 550 or 555 is not present, one or more gate regions extend beyond the corresponding center line 511 or 512 to be longer than the gate regions 530, 532, 534. Example configurations with gate regions of different lengths are described with respect to FIG. 8D.

The layout 500 further comprises source/drain contacts, such as MD contacts and BMD contacts, alternatingly arranged with the gate regions along the X axis. For example, a BMD contact 520, and MD contacts 522, 524 are illustrated in FIG. 5, whereas other MD contacts and BMD contacts are not shown for simplicity. Each MD contact overlies a corresponding BMD contact. For example, the layout 500 comprises an MD contact (not shown) which is over the BMD contact 520 and is immediately adjacent to the MD contact 522. Two MD contacts (or BMD contacts) are considered directly adjacent (or immediately adjacent) where there are no other MD contacts (or BMD contacts) therebetween. A pitch, i.e., a center-to-center distance along the X axis, between directly adjacent MD contacts (or BMD contacts) is the same as the pitch CPP between directly adjacent gate regions. Like the gate regions, the MD contacts and BMD contact are elongated along the Y axis.

The layout 500 further comprises via interconnect regions (labelled as “PV”) which correspond to via interconnects embedded in a gate length defining dielectric structure in a manufactured IC device corresponding to the layout 500. For simplicity, a via interconnect region in a layout is sometimes also referred to as a via interconnect. For example, the layout 500 comprises, over the CMG region 550, via interconnects 560, 562, 564 elongated, and aligned with each other, along the X axis. The via interconnects 560, 562, 564 are cut or disconnected from each other by cut-PV regions 561, 563 of a cut-PV mask. In a manufactured IC device corresponding to the layout 500, the cut-PV regions 561, 563 correspond to dielectric structures that electrically isolate adjacent via interconnects from each other. In the example configuration in FIG. 5, the cut-PV regions 561, 563 configure the lengths of the via interconnects 560, 562, 564. For example, a length L1 of the via interconnect 560 along the X axis is defined by and between the cut-PV regions 561, 563. In some embodiments, different via interconnects 560, 562, 564 have different lengths. For example, a length L2 of the via interconnect 560 for power delivery as described herein is shorter than the length L1 of the via interconnect 562 for signal transmission as described herein.

In some embodiments, the via interconnect 560 for power delivery corresponds to the via interconnect 360 described with respect to FIGS. 3A, 4A. Specifically, in the layout 500, the MD contact 524 overlaps the via interconnect 560, which overlaps a conductor 536, which overlaps a BVD via 576, which overlaps a VSS power rail (not shown) elongated along the track BM0_1, in correspondence with the MD contact 324 overlapping the via interconnect 360, which overlaps the conductor 336, which overlaps the BVD via 376, which overlaps the power rail 391, as described with respect to FIGS. 3A, 4A. In some embodiments, an entirety of at least one of the conductor 536 or the BVD via 576 is overlapped by the MD contact 524, the via interconnect 560 and the VSS power rail. In at least one embodiment, an entirety of the via interconnect 560 is overlapped by the VSS power rail. In at least one embodiment, at least one of the described overlapping relationships among the conductor 536, the BVD via 576, the MD contact 524, the via interconnect 560 and the VSS power rail ensures that large contact areas among the described components are achieved, which reduces resistance of the corresponding electrical connection and avoids unacceptable or undesirable voltage drop (IR drop). The conductor 536 is a BMD contact and is illustrated in a manner similar to the BMD contact 520. However, the conductor 536 does not overlap the active region OD, and is not configured to form an electrical contact with a source/drain.

In some embodiments, the via interconnect 562 for signal transmission corresponds to the via interconnect 360 described with respect to FIGS. 3B, 4B. Specifically, in the layout 500, the MD contact 522 overlaps the via interconnect 562 which overlaps the BMD contact 520, in correspondence with the MD contact 324 overlapping the via interconnect 360 which overlaps the BMD contact 338, described with respect to FIGS. 3B, 4B. Similar to the example configuration described with respect to FIG. 4B, the via interconnect 562 is configured to provide an electrical connection between a top source/drain in the active region OD under the MD contact 522 and a bottom source/drain in the active region OD over the BMD contact 520, of the same CFET device 582. Other configurations are within the scopes of various embodiments. For example, in at least one embodiment, the cut-PV region 563 is omitted, or reduced in length, and the via interconnect 562 extends further along the X axis (e.g., to the left side in FIG. 5) to provide an electrical connection between the top source/drain under the MD contact 522 and a bottom source/drain of a CFET device other than the CFET device 582. As can be seen in FIG. 5, the via interconnect 562 intersects multiple planes correspondingly containing multiple gate regions 530, 532, 534 of different CFET devices 580, 582, 584. The multiple planes are schematically represented in FIG. 5A by the center lines of the gate regions 530, 532, 534.

In some embodiments, to ensure manufacturability of an IC device corresponding to the layout 500, one or more design rules are to be satisfied. A design rule related to one or more via interconnects described herein is the following dimension relationship along the Y axis:

$$CH = 1 / 2 W\_CMG + S 1 + W\_OD \_max + S 2 + 1 / 2 W\_PV$$

W_CMG is a width of the CMG region 555 along the Y axis. S1 (min gate end) is a predetermined minimal acceptable length by which a gate region projects along the Y axis beyond the underlying active region. S1 is also the spacing along the Y axis between the active region and the adjacent CMG region. W_OD_max is a predetermined maximal acceptable width of the active region along the Y axis. S2 is a predetermined acceptable spacing along the Y axis between the active region and an adjacent via interconnect. W_PV is a width of the via interconnect along the Y axis. In some embodiments, the via interconnect, e.g., the width W_PV of the via interconnect, is configured to satisfy the above dimension relationship.

As can be seen in FIG. 5, the M0 layer and BM0 layer are schematically represented by corresponding M0 tracks M0_1-M0_4, and BM0 tracks BM0_1-BM0_3. Metal patterns (not shown) on one or more of the tracks M0_1-M0_4 and tracks BM0_1-BM0_3 provide internal routing among various CFET devices to couple the CFET devices with each other and with power supply voltages VDD, VSS to obtain circuitry configured to perform a predetermined operation or function. In addition to the described tracks M0_1-M0_4 and tracks BM0_1-BM0_3, the layout 500 further comprises one or more via interconnects (PV) which extend along the X axis like the tracks M0_1-M0_4 and tracks BM0_1-BM0_3, and provide additional resources for routing. As a result, it is possible in one or more embodiments to achieve one or more advantages including, but not limited to, improved routing efficiency, simplified routing tasks, or the like. One or more further advantages described herein are achievable by the layout 500 and/or by a manufactured IC device corresponding to the layout 500, in accordance with some embodiments.

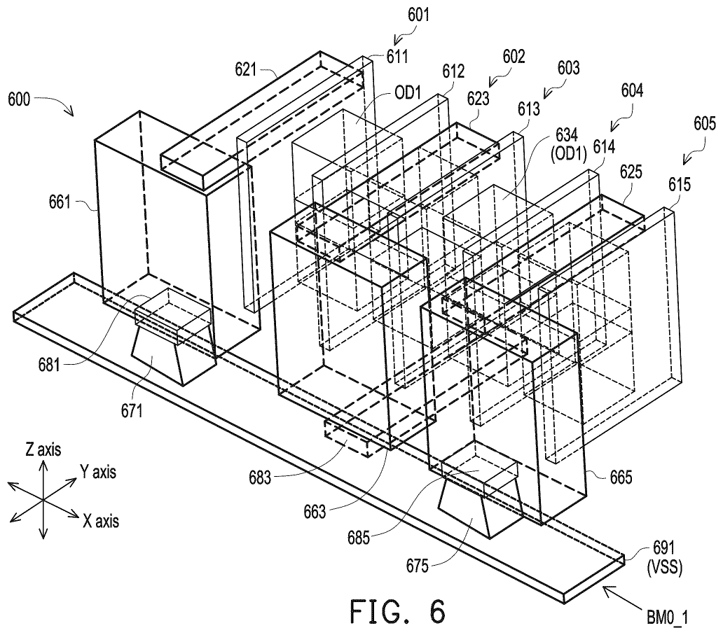

FIG. 6 is a schematic perspective view of a circuit region of an IC device 600, in accordance with some embodiments. In some embodiments, the IC device 600 corresponds to one or more of the IC devices 200A, 300A, 300B, 400A, 400B, or to one or more of the layouts 200B, 500. Components in FIG. 6 having corresponding components in FIGS. 2B, 3A, 3B, 4A, 4B, 5 are designated by the same reference numerals as in FIGS. 2B, 3A, 3B, 4A, 4B, 5.

The IC device 600 comprises a plurality of CFET devices 601-605 arranged along the X axis. In some embodiments, each of the CFET devices 601-605 corresponds to the device stack 100A. The CFET devices 601-605 comprise corresponding gates 611-615 extending across an active region which comprises a top active region OD1 and a bottom active region (not shown in FIG. 6). Areas of the active region on opposite sides of a gate region form source/drains of the corresponding CFET device. The IC device 600 comprises an MD contact 621 over and in electrical contact with a top source/drain of the CFET device 601 on the left side (in FIG. 6) of the gate 611, an MD contact 623 over and in electrical contact with a common top source/drain of the CFET devices 602, 603 between the gates 612, 613, and an MD contact 625 over and in electrical contact with a common top source/drain of the CFET devices 604, 605 between the gates 614, 615. The IC device 600 further comprises via interconnects 661, 663, 665, BMD contacts 681, 683, 685, BVD vias 671, 675, and a back side power rail 691 configured to supply a power supply voltage, e.g., VSS, to the top semiconductor device(s) of one or more of CFET devices 601-605.

The MD contact 621 is electrically coupled by the via interconnect 661, the BMD contact 681 and the BVD via 671 to the power rail 691. In other words, the via interconnect 661 is configured for power delivery, in a manner similar to that described with respect to FIGS. 3A, 4A, 5.

The MD contact 623 is electrically coupled by the via interconnect 663 to the BMD contact 683. In other words, the via interconnect 663 is configured for signal transmission, in a manner similar to that described with respect to FIGS. 3B, 4B, 5. As a result, the top source/drain under the MD contact 623 is electrically coupled to a bottom source/drain of the CFET device 603 which is under the other top source/drain 634 of the CFET device 603.

The MD contact 625 is electrically coupled by the via interconnect 665, the BMD contact 685 and the BVD via 675 to the power rail 691. In other words, the via interconnect 665 is configured for power delivery, in a manner similar to that described with respect to FIGS. 3A, 4A, 5.

In the example configuration in FIG. 6, each of the via interconnects 661, 665 for power delivery is configured to provide power from the power rail 391 on the back side to one top semiconductor device, e.g., the top semiconductor device of the CFET device 601 or the top semiconductor device of the CFET device 605. This configuration is sometimes referred to as “power via”.

In some embodiments, a via interconnect is configured to provide power from the power rail 391 on the back side to more than one top semiconductor devices. For example, in one or more embodiments, the via interconnect 663 is omitted, and the via interconnects 661, 665 are continuous to each other and configure an elongated via interconnect extending continuously along the X axis across all gates 611-615. This configuration is sometimes referred to as “power wall”. The MD contact 623 and BMD contact 683 are omitted or shortened to avoid electrical contact with the power wall. The power wall extends continuously along the X axis and provides power from the power rail 391 on the back side to more than one top semiconductor devices, e.g., to the top semiconductor devices of the CFET devices 601, 605.

In the example configuration in FIG. 6, the via interconnect 663 for signal transmission is configured to electrically couple a top source/drain (under the MD contact 623) and a bottom source/drain (under the top source/drain 634) of the same CFET device 603. The via interconnect 663 is similar to a power via as described, but is configured for signal transmission.

In some embodiments, a via interconnect comprises a structure elongated along the X axis like a power wall as described, but is configured for signal transmission. For example, in one or more embodiments, the BVD via 671 is omitted, and the via interconnects 661, 663 are continuous to each other and configure an elongated via interconnect extending continuously along the X axis across at least gates 611-613. The MD contact 621 is omitted or shortened to avoid electrical contact with the elongated via interconnect. The BMD contact 681 is extended, like the BMD contact 683, to come in contact with the bottom source/drain of the CFET device 601 below the MD contact 621. As a result, the elongated via interconnect couples a top source/drain (under the MD contact 623) of the CFET device 603 with a bottom source/drain (over the extended BMD contact 681) of another CFET device, i.e., the CFET device 601. Other configurations are within the scopes of various embodiments. One or more advantages described herein are achievable by the IC device 600, in accordance with some embodiments.

Each of FIGS. 7A-7F includes a schematic circuit diagram of a circuit region and schematic views at various layers of a corresponding layout of the circuit region, in accordance with some embodiments. In some embodiments, the circuit region in each of FIGS. 7A-7F corresponds to a circuit region of one or more of IC devices 200A, 300A, 300B, 400A, 400B, 600, and/or one or more of the layouts 200B, 500. Components in FIGS. 7A-7F having corresponding components in FIGS. 2B, 3A, 3B, 4A, 4B, 5, 6 are designated by the same reference numerals as in FIGS. 2B, 3A, 3B, 4A, 4B, 5, 6.

In FIG. 7A, the circuit region is an inverter (INV). The inverter INV comprises an NMOS transistor N1 and a PMOS transistor P1 coupled in series between VSS and VDD. Gates of the transistors N1, P1 are coupled to an input IN. A common source/drain of the transistors N1, P1 is coupled to an output ZN1. In at least one embodiment, the inverter INV is implemented by one or more CFET devices having the top semiconductor devices corresponding to the transistor N1, and the bottom semiconductor devices corresponding to the transistor P1.

A layout 700A in FIG. 7A is a layout of a cell INVD1, in accordance with some embodiments. The cell INVD1 represented by the layout 700A corresponds to the inverter INV, and includes one CFET device with one top semiconductor device corresponding to the transistor N1, and one bottom semiconductor device corresponding to the transistor P1. The layout 700A comprises an upper layer 751 and a lower layer 752. The layout 700A further comprises a boundary 710 (i.e., cell boundary). In some embodiments, the boundary 710 corresponds to the boundary of one or more of the cells C1-C4 described with respect to FIG. 2B. The boundary 710 comprises edges 711, 712, 713, 714. The edges 711, 712 are elongated along the X axis, and the edges 713, 714 are elongated along the Y axis. In some embodiments, the X axis is an example of one of a first direction and a second direction, and the Y axis is an example of the other of the first direction and the second direction. The edges 711, 712, 713, 714 are connected together to form the closed boundary 710. In a place-and-route operation (also referred to as “automated placement and routing (APR)”) described herein, cells are placed in an IC layout in abutment with each other at their respective boundaries. The rectangular shape of the boundary 710 is an example. Other boundary shapes for various cells are within the scope of various embodiments. The cell represented by the layout 700A has a cell height of 1 CH.

The upper layer 751 includes the top semiconductor device, e.g., transistor N1, of the corresponding CFET device. The upper layer 751 comprises an NMOS active region OD_51, a functional gate region G1 schematically represented by its center line, MD contacts MD_50, MD_51, an MDLI interconnect MDLI_51, CMG regions CMG_51, CMG_52, and a via interconnect PV_50. In some embodiments, the layout 700A further comprises one or more M0 metal patterns (not shown) along one or more of the tracks M0_1-M0_4. The edges 711, 712 of the boundary 710 correspondingly coincide with the center lines of the regions CMG_51, CMG_52. In some embodiments, the layout 700A further comprises dummy gate regions (not shown) correspondingly on the edges 713, 714 of the boundary 710.

The lower layer 752 includes the bottom semiconductor device, e.g., transistor P1, of the corresponding CFET device. The boundary 710, regions CMG_51, CMG_52, interconnect MDLI_51 and via interconnect PV_50 are common for both the upper layer 751 and the lower layer 752. The lower layer 752 further comprises a PMOS active region OD_52, BMD contacts BMD_50, BMD_50′, BMD_51, BVD vias BVD_50, BVD_50′, and VSS and VDD power rails (not shown) correspondingly on the tracks BM0_1, BM0_3. In some embodiments, the layout 700A further comprises one or more BM0 metal patterns (not shown) along the track BM0_2. The functional gate regions of the transistors N1, P1 are electrically coupled to each other (e.g., by an MGLI interconnect) and are designated by the same reference numeral, i.e., gate region G1. As can be seen in FIG. 7A, the contact BMD_50′ for the via interconnect PV_50 and VSS is spaced, along the Y axis, from the contact BMD_50 for VDD.

The gate region G1 corresponds to the input IN. The source of the transistor P1 is electrically coupled by the contact BMD_50 and via BVD_50 to the VDD power rail on the track BM0_3. The drains of the transistors N1, P1 are electrically coupled together by the interconnect MDLI_51, and the corresponding contacts MD_51, BMD_51 correspond to the output ZN1.

The source of the transistor N1 is electrically coupled by the contact MD_50, via interconnect PV_50, contact BMD_50′ and via BVD_50′ to the VSS power rail on the track BM0_1. Thus, power is provided from the back side power delivery network to the top semiconductor device N1, through the via interconnect PV_50, in a manner as described herein.

In FIG. 7B, the circuit region is a two-input NOR gate (NR2). The NR2 gate comprises NMOS transistors N2, N3, and PMOS transistors P2, P3. The transistors N2, N3 are coupled in parallel between VSS and an output ZN2. The transistors P2, P3 are coupled in series between the output ZN2 and VDD. Gates of transistors N2, P2 are electrically coupled to a first input IN1. Gates of transistors N3, P3 are electrically coupled to a second input IN2. In at least one embodiment, the NR2 gate is implemented by one or more first CFET devices having the top semiconductor devices corresponding to the transistor N2 and the bottom semiconductor devices corresponding to the transistor P2, and one or more second CFET devices having the top semiconductor devices corresponding to the transistor N3 and the bottom semiconductor devices corresponding to the transistor P3.

A layout 700B in FIG. 7B is a layout of a cell NR2D1, in accordance with some embodiments. The cell NR2D1 represented by the layout 700B corresponds to the NR2 gate, and includes first and second CFET devices. The first CFET device configures the transistors N2, P2. The second CFET device configures the transistors N3, P3. The layout 700B comprises an upper layer 761 and a lower layer 762. The layout 700B further comprises a boundary 720 corresponding to the boundary 710. The cell represented by the layout 700B has a cell height of 1 CH.

The upper layer 761 includes the top semiconductor devices, e.g., transistors N2, N3, of the corresponding CFET devices. The upper layer 761 comprises an NMOS active region OD_61, gate regions G2, G3 schematically represented by their center lines, MD contacts MD_60, MD_61, MD_62, an MDLI interconnect MDLI_62, CMG regions CMG_61, CMG_62, and a via interconnect PV_61. In some embodiments, the layout 700B further comprises one or more M0 metal patterns (not shown) along one or more of the tracks M0_1-M0_4, and/or dummy gate regions on corresponding edges of the boundary 720.

The lower layer 762 includes the bottom semiconductor devices, e.g., transistors P2, P3, of the corresponding CFET device. The boundary 720, regions CMG_61, CMG_62, interconnect MDLI_62 and via interconnect PV_61 are common for both the upper layer 761 and the lower layer 762. The lower layer 762 further comprises a PMOS active region OD_62, BMD contacts BMD_60, BMD_61, BMD_61′, BMD_62, BVD vias BVD_60, BVD_61, and VSS and VDD power rails (not shown) correspondingly on the tracks BM0_1, BM0_3. In some embodiments, the layout 700B further comprises one or more BM0 metal patterns (not shown) along the track BM0_2. The functional gate regions of the transistors N2, P2 are electrically coupled to each other (e.g., by an MGLI interconnect) and are designated by the same reference numeral, i.e., gate region G2. The functional gate regions of the transistors N3, P3 are electrically coupled to each other (e.g., by an MGLI interconnect) and are designated by the same reference numeral, i.e., gate region G3. As can be seen in FIG. 7B, the contact BMD_61′ for the via interconnect PV_61 and VSS is spaced, along the Y axis, from the contact BMD_61.

The gate regions G2, G3 correspond to the inputs IN1, IN2. The source of the transistor P2 is electrically coupled by the contact BMD_60 and via BVD_60 to the VDD power rail on the track BM0_3. The drains of the transistors N3, P3 are electrically coupled together by the interconnect MDLI_62, and the corresponding contacts MD_62, BMD_62 correspond to the output ZN2.

The common source of the transistors N2, N3 is electrically coupled by the contact MD_61, via interconnect PV_61, contact BMD_61′ and via BVD_61 to the VSS power rail on the track BM0_1. Thus, power is provided from the back side power delivery network to the top semiconductor devices N2, N3, through the via interconnect PV_61, in a manner as described herein.

In FIG. 7C, the circuit region is a two-input two-output AND-OR-Invert (AOI22) logic. The AOI22 logic comprises inputs A1, A2, B1, B2, an output ZN3, and transistors PA1, PA2, PB1, PB2, NA1, NA2, NB1, NB2. Gates of the transistors PA1, NA1 are electrically coupled to the input A1. Gates of the transistors PA2, NA2 are electrically coupled to the input A2. Gates of the transistors PB1, NB1 are electrically coupled to the input B1. Gates of the transistors PB2, NB2 are electrically coupled to the input B2. Sources of the transistors PB1, PB2 are electrically coupled to VDD. Drains of the transistors PB1, PB2 are electrically coupled to a node CON. Sources of the transistors PA1, PA2 are electrically coupled to the node CON. Drains of the transistors PA1, PA2 are electrically coupled to the output ZN3. The transistors NA1, NA2 are electrically coupled in series between VSS and the output ZN3. The transistors NB1, NB2 are electrically coupled in series between VSS and the output ZN3.

A layout 700C in FIG. 7C is a layout of a cell AOI22D1, in accordance with some embodiments. The cell AOI22D1 represented by the layout 700C corresponds to the AOI22 logic, and includes first through fourth CFET devices. The transistors NA1, PA1 are correspondingly top and bottom semiconductor devices of the first CFET device, the transistors NA2, PA2 are correspondingly top and bottom semiconductor devices of the second CFET device, the transistors NB1, PB1 are correspondingly top and bottom semiconductor devices of the third CFET device, and the transistors NB2, PB2 are correspondingly top and bottom semiconductor devices of the fourth CFET device. The layout 700C comprises an upper layer 771 and a lower layer 772. The layout 700C further comprises a boundary 730 corresponding to the boundary 710. The cell represented by the layout 700C has a cell height of 1 CH.

The upper layer 771 includes the top semiconductor devices, e.g., transistors NA1, NA2, NB1, NB2, of the corresponding CFET devices. The upper layer 771 comprises an NMOS active region OD_71, gate regions G4-G7 schematically represented by their center lines, MD contacts MD_70-MD_74, CMG regions CMG_71, CMG_72, and via interconnects PV_70, PV_72, PV_74. In some embodiments, the layout 700C further comprises one or more M0 metal patterns (not shown) along one or more of the tracks M0_1-M0_4, and/or dummy gate regions on corresponding edges of the boundary 730.

The lower layer 772 includes the bottom semiconductor devices, e.g., transistors PA1, PA2, PB1, PB2, of the corresponding CFET devices. The boundary 730, regions CMG_71, CMG_72, and via interconnects PV_70, PV_72, PV_74 are common for both the upper layer 771 and the lower layer 772. The lower layer 772 further comprises a PMOS active region OD_72, BMD contacts BMD_70-BMD_74, BMD_70′ and BMD_74′, BVD vias BVD_70, BVD_71, BVD_74, and VSS and VDD power rails (not shown) correspondingly on the tracks BM0_1, BM0_3. In some embodiments, the layout 700C further comprises one or more BM0 metal patterns (not shown) along the track BM0_2. The functional gate regions of each pair of corresponding transistors, i.e., NA1 and PA1, NA2 and PA2, NB1 and PB1, NB2 and PB2, are electrically coupled to each other (e.g., by an MGLI interconnect) and are designated by the same reference numeral, i.e., gate regions G6, G7, G5, G4. As can be seen in FIG. 7C, the contact BMD_70′ for the via interconnect PV_70 and VSS is spaced, along the Y axis, from the contact BMD_70, and the contact BMD 74′ for the via interconnect PV_74 and VSS is spaced, along the Y axis, from the contact BMD_74.

The gate regions G4-G7 correspond to the inputs B2, B1, A1, A2. The common source of the transistors PB1, PB2 is electrically coupled by the contact BMD_71 and via BVD_71 to the VDD power rail on the track BM0_3. The contacts BMD_70, BMD_72, BMD_74 correspond to the node CON. The contacts MD_72, BMD_73 correspond to the output ZN3.

The source of the transistor NB2 is electrically coupled by the contact MD_70, via interconnect PV_70, contact BMD_70′ and via BVD_70 to the VSS power rail on the track BM0_1. The source of the transistor NA2 is electrically coupled by the contact MD_74, via interconnect PV_74, contact BMD_74′ and via BVD_74 to the VSS power rail on the track BM0_1. Thus, power is provided from the back side power delivery network to the top semiconductor devices NB2, NA2, through the via interconnects PV_70, PV_74, in a manner as described herein.

The common drain of the transistors NA1, NB1 is electrically coupled by the contact MD_72, via interconnect PV_72, contact BMD_73 to the common drain of the transistors PA1, PA2. Thus, the via interconnect PV_72 is configured for signal transmission to electrically couple a top source/drain to a bottom source/drain, as described herein.

In FIG. 7D, the circuit region is a two-input multiplexer (MUX2) with two inputs I0, I1, a selection input S, and an output ZN4. In some embodiments, the MUX2 is configured from one or more NOR gates as described with respect to FIG. 7B and/or one or more inverters as described with respect to FIG. 7A.

A layout 700D in FIG. 7D is a layout of a cell MUX2D1, in accordance with some embodiments. The cell MUX2D1 represented by the layout 700D corresponds to the MUX2, and includes eight CFET devices each configuring a corresponding pair of a top semiconductor device (e.g., an NMOS transistor) and a bottom semiconductor device (e.g., a PMOS transistor). For simplicity, gate regions of the CFET devices are not illustrated in FIG. 7D. The layout 700D comprises an upper layer 781 and a lower layer 782. The layout 700D further comprises a boundary 740 corresponding to the boundary 710. The cell represented by the layout 700D has a double cell height of 2 CH.

The upper layer 781 includes the top semiconductor devices, e.g., NMOS transistors of the corresponding CFET devices. The upper layer 781 comprises two NMOS active regions OD_80, OD_81 each configuring four NMOS transistors, MD contacts MD_80-MD_88, CMG regions CMG_81, CMG_82, CMG_83, various MDLI interconnects, and via interconnects PV_81, PV_86. In some embodiments, the layout 700D further comprises one or more M0 metal patterns (not shown) along one or more of the tracks M0_1-M0_8, and/or dummy gate regions on corresponding edges of the boundary 740.

The region CMG_82 extends over half a width of the cell along the X axis. In a region where the region CMG_82 is present, gate regions over the active region OD_80 are isolated from corresponding gate regions over the gate regions over the active region OD_81. In a region where the region CMG_82 is not present, gate regions extend continuously along the Y axis over both the active regions OD_80, OD_81. The contact MD_84 extends continuously along the Y axis over both the active regions OD_80, OD_81. Each of the MDLI interconnects electrically couples a top source/drain and a underlying bottom source/drain as described herein. For example, an MDLI interconnect MDLI_80 electrically couples the top source/drain corresponding to the contact MD_80 and the underlying bottom source/drain corresponding to a contact BMD_80. For simplicity, other MDLI interconnects are shown for MD contacts MD_82, MD_84, MD_85, MD_87, but not numbered. The tracks M0_1-M0_8 are symmetrical across a center line of the region CMG_82.

The lower layer 782 includes the bottom semiconductor devices, e.g., PMOS transistors of the corresponding CFET devices. The boundary 740, regions CMG_81-CMG_83, the MDLI interconnects, and via interconnects PV_81, PV_86 are common for both the upper layer 781 and the lower layer 782. The lower layer 782 further comprises two PMOS active regions OD_82, OD_83 correspondingly under the NMOS active regions OD_80, OD_81. Each of the active regions OD_82, OD_83 configures four PMOS transistors. The lower layer 782 further includes BMD contacts BMD_80-BMD_85, BMD_87 and BMD_88, BVD vias BVD_81, BVD_86, BVD_81′, BVD_86′, two VSS power rails (not shown) correspondingly on the track BM0_1 and a track BM0_5, and a VDD power rail (not shown) on the track BM0_3. In some embodiments, the layout 700D further comprises one or more BM0 metal patterns (not shown) along the track BM0_2 and/or a track BM0_4. The tracks BM0_1-BM0_5 are symmetrical across the center line of the region CMG_82.

Each of the contacts BMD_81, BMD_84 extends continuously along the Y axis over both the active regions OD_82, OD_83. A BMD contact (not shown) is between the via BVD_81′ and the via interconnect PV_81, and is spaced along the Y axis from the contact BMD_81. A further BMD contact (not shown) is between the via BVD_86′ and the via interconnect PV_86, and is spaced along the Y axis from the contact BMD_81. Bottom source/drains corresponding to the contact BMD_81 are electrically coupled by the contact BMD_81 and vias BVD_81, BVD_86 to the VDD power rail on the track BM0_3.

A top source/drain is electrically coupled by the contact MD_81, via interconnect PV_81, a BMD contact (not shown) and via BVD_81′ to the VSS power rail on the track BM0_5. A further top source/drain is electrically coupled by the contact MD_86, via interconnect PV_86, a BMD contact (not shown) and via BVD_86′ to the VSS power rail on the track BM0_1. Thus, power is provided from the back side power delivery network to the corresponding top semiconductor devices, through the via interconnects PV_81, PV_86, in a manner as described herein.

The layout 700D is an example of a cell having a via interconnect on the boundary of the cell, i.e., via interconnects PV_81, PV_86 are on corresponding edges of the boundary 740. Other configurations where a call has a via interconnect inside (or surrounded by) the boundary of the cell are within the scopes of various embodiments, for example, as described with respect to FIG. 7E.

In FIG. 7E, the circuit region is the MUX2 described with respect to FIG. 7D. A layout 700E in FIG. 7E is a layout of a cell MUX2D1, in accordance with some embodiments. The cell MUX2D1 represented by the layout 700E corresponds to the MUX2, and includes eight CFET devices each configuring a corresponding pair of a top semiconductor device (e.g., an NMOS transistor) and a bottom semiconductor device (e.g., a PMOS transistor). For simplicity, gate regions of the CFET devices are not illustrated in FIG. 7E. The layout 700E comprises the upper layer 781 and the lower layer 782. The layout 700E further comprises a boundary 750 corresponding to the boundary 710. The cell represented by the layout 700E has a double cell height of 2 CH.

The upper layer 781 includes the top semiconductor devices, e.g., NMOS transistors of the corresponding CFET devices. The upper layer 781 comprises two NMOS active regions OD_81, OD_85 each configuring four NMOS transistors, MD contacts MD_80, MD_82-MD_85, MD_87-MD_89, CMG regions CMG_81, CMG_84, CMG_85, various MDLI interconnects, various VD vias, and via interconnects PV_89. In some embodiments, the layout 700E further comprises one or more M0 metal patterns (not shown) along one or more of the tracks M0_1-M0_4 and M0_9-M0_11, and/or dummy gate regions on corresponding edges of the boundary 750.

The contacts MD_84, MD_89 extend continuously along the Y axis over both the active regions OD_81, OD_85. Each of the MDLI interconnects electrically couples a top source/drain and a underlying bottom source/drain as described herein with respect to the interconnect MDLI_80. Each of the VD vias electrically couples a underlying MD contact and a corresponding overlying M0 metal pattern. For example, two vias VD_3, VD_10 electrically couple the underlying MD contact MD_84 correspondingly to overlying M0 metal patterns on the tracks M0_3, M0_10. For simplicity, other VD vias are shown for MD contacts MD_80, MD_83, MD_85, MD_88, but not numbered. The tracks M0_9-M0_11 are symmetrical to the tracks M0_2-M0_4 across a center line of the region CMG_81.

The lower layer 782 includes the bottom semiconductor devices, e.g., PMOS transistors of the corresponding CFET devices. The boundary 750, regions CMG_81, CMG_84, CMG_85, the MDLI interconnects, and via interconnect PV_89 are common for both the upper layer 781 and the lower layer 782. The lower layer 782 further comprises two PMOS active regions OD_83, OD_87 correspondingly under the NMOS active regions OD_81, OD_85. Each of the active regions OD_83, OD_87 configures four PMOS transistors. The lower layer 782 further includes BMD contacts BMD_80, BMD_82-BMD_89, BVD vias BVD_86, BVD_89, two VDD power rails (not shown) correspondingly on the track BM0_3 and a track BM0_7, and a VSS power rail (not shown) on the track BM0_1. In some embodiments, the layout 700E further comprises one or more BM0 metal patterns (not shown) along the track BM0_2 and/or a track BM0_6. The tracks BM0_6-BM0_7 are symmetrical to the tracks BM0_2-BM0_3 across the center line of the region CMG_81.

The contact BMD_84 extends continuously along the Y axis over both the active regions OD_83, OD_87. A BMD contact (not shown) is between the via BVD_89′ and the via interconnect PV_89, and is spaced along the Y axis from the contacts BMD_86, BMD_89. Bottom source/drains corresponding to the contacts BMD_86, BMD_89 are electrically coupled by the contacts BMD_86, BMD_89 and corresponding vias BVD_86, BVD_89 to the corresponding VDD power rails on the tracks BM0_7, BM0_3.

Top source/drains in the active regions OD_81, OD_85 are electrically coupled by the contact MD_89, via interconnect PV_89, a BMD contact (not shown) and via BVD_89′ to the VSS power rail on the track BM0_1. Thus, power is provided from the back side power delivery network to the corresponding top semiconductor devices, through the via interconnect PV_89, in a manner as described herein. As can be seen in FIG. 7E, the via interconnect PV_89 is arranged inside the boundary 750. In some embodiments, when two cells of the single cell height are placed in abutment, via interconnects on the boundaries of the two cells are merged into one via interconnect that is shared by the two cells, resulting in a layout similar to the IC layout 700E with the shared via interconnect arranged in the middle, between the two cells.

In at least one embodiment, at least one of the layouts 700A-700E is stored as a standard cell in at least one library on a non-transitory computer-readable recording medium, and is read out and placed into a layout of an IC device to be designed and/or manufactured. In at least one embodiment, one or more advantages described herein are achievable by one or more of the layouts 700A-700E, and/or IC devices corresponding to one or more of the layouts 700A-700E.

FIG. 8A includes a schematic diagram of a portion of an IC manufacturing process 800A, and schematic views of an IC device at various stages in the manufacturing process, in accordance with some embodiments. In some embodiments, the process 800A is performed to manufacture one or more of the IC devices 200A, 300A, 300B, 400A, 400B, 600, and/or in accordance with one or more of the layouts 200B, 500, 700A-700E. The process 800A comprises operations 802, 804, 806, 808.

At operation 802, a semiconductor structure 820 is formed. In at least one embodiment, one or more operations described with respect to FIGS. 1B-1F are performed to obtain the semiconductor structure 820. The semiconductor structure 820 comprises a plurality of elongated, continuous gate structures 830, 840, 850, 860, 870 extending across first and second active regions 821, 822. Each of the active regions 821, 822 comprises a bottom active region and a top active region stacked over the bottom active region, as described herein. Each of the gate structures 830, 840, 850, 860, 870 comprises a first all-around gate extending around one or more channels in the top active region, and a second all-around gate extending around one or more channels in the bottom active region, as described herein.

At operation 804, CMG openings 881, 882, 883 are formed, e.g., by etching, in the semiconductor structure 820 using a CMG mask. This operation is sometimes referred to as CMG patterning. Each of the CMG openings 881, 882, 883 corresponds to a CMG region, as described herein. Each of the CMG openings 881, 882, 883 extends through an entire thickness, or height, of the gate structures 830, 840, 850, 860, 870, to cut or severe each of the gate structures 830, 840, 850, 860, 870 into disconnected sections. For example, the gate structures 830, 840, 850, 860, 870 are cut into corresponding gate structures 831 and 832, 841 and 842, 851 and 852, 861 and 862, 871 and 872. For simplicity, in the subsequent operations, the gate structures 832, 842, 852, 862, 872, the active region 822, and structures corresponding to the CMG opening 883 are not illustrated.

At operation 806, a conformal deposition of a dielectric material is performed, to deposit the dielectric material over side walls of a CMG opening where a via interconnect is to be later formed. In an example process, a conformal deposition process, such as ALD, is performed to deposit a conformal layer 885 of the dielectric material over side walls of the CMG opening 882, followed by an anisotropic etching to remove portions of the conformal layer other than the portions on the side walls of the CMG opening 882. As a result, a middle region 886 of the CMG opening 882 remains unfilled. Other CMG openings where a via interconnect is not to be formed later are filled with a dielectric material to form corresponding dielectric structures. For example, the CMG opening 881 is filled with a dielectric material to obtain a dielectric structure 884.

At operation 808, a conductive material is deposited in the unfilled middle region 886 of the CMG opening 882, to obtain a via interconnect 887. In some embodiments, the via interconnect 887 corresponds to one or more of the via interconnects described herein, and the layer 885 of the dielectric material corresponds to one or more of the dielectric structures surrounding such via interconnects, as described herein. In at least one embodiment, the via interconnect 887 corresponds to a power wall as described herein.

In the described example process 800A, an extra mask is not required for the formation of the via interconnect 887. Specifically, the via interconnect 887 is self-aligned, and formed by the CMG mask. In at least one embodiment, this is an advantage, because the manufacturing process is not significantly complicated by the formation of via interconnects. In at least one embodiment, one or more advantages described herein are achievable by one or more IC devices manufactured in accordance with the process 800A.

FIG. 8B includes a schematic diagram of a portion of an IC manufacturing process 800B, and schematic views of an IC device at various stages in the manufacturing process, in accordance with some embodiments. In some embodiments, the process 800B is performed to manufacture one or more of the IC devices 200A, 300A, 300B, 400A, 400B, 600, and/or in accordance with one or more of the layouts 200B, 500, 700A-700E. Components in FIG. 8B having corresponding components in FIG. 8A are designated by the same reference numerals as in FIG. 8A.

The process 800B comprises operations 802 and 804 as described with respect to FIG. 8A, and operations 810, 812, 814. For simplicity, operation 802 and various features of operation 804 are not illustrated in FIG. 8B, and the description of operation 804 is not repeated.

At operation 810, a dielectric material is deposited in all CMG openings to form corresponding dielectric structures. For example, the CMG openings 881, 882 are filled with a dielectric material to obtain corresponding dielectric structures 884, 895.

At operation 812, a via patterning process is performed to form a via opening in a dielectric structure where a via interconnect is to be formed later. For example, an etching process is performed using an additional mask to form a via opening 896 in the dielectric structure 895.

At operation 814, a conductive material is deposited in the via opening 896, to obtain a via interconnect 897. In some embodiments, the via interconnect 897 corresponds to one or more of the via interconnects described herein, and the dielectric structure 895 corresponds to one or more of the dielectric structures surrounding such via interconnects, as described herein. In at least one embodiment, the via interconnect 897 corresponds to a power via as described herein. In at least one embodiment, one or more advantages described herein are achievable by one or more IC devices manufactured in accordance with the process 800B.

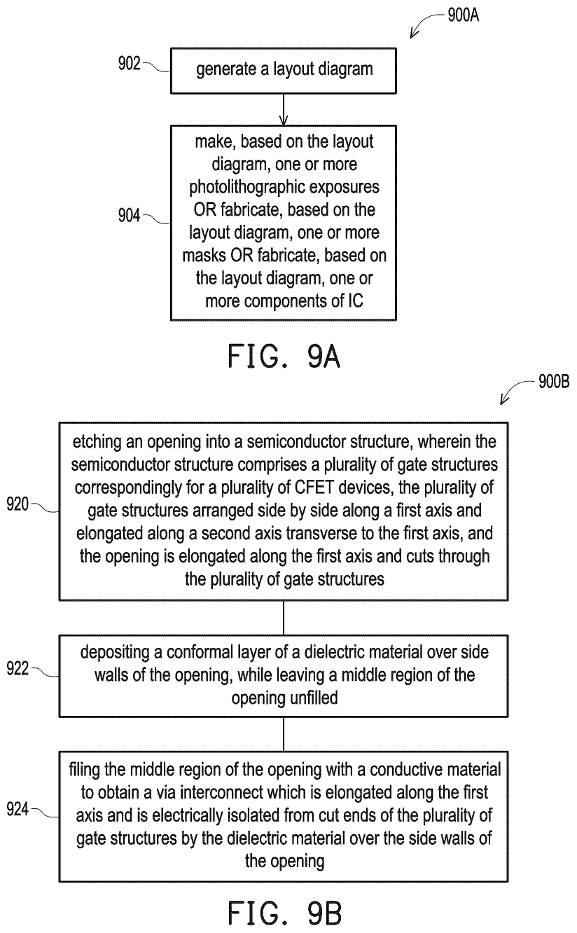

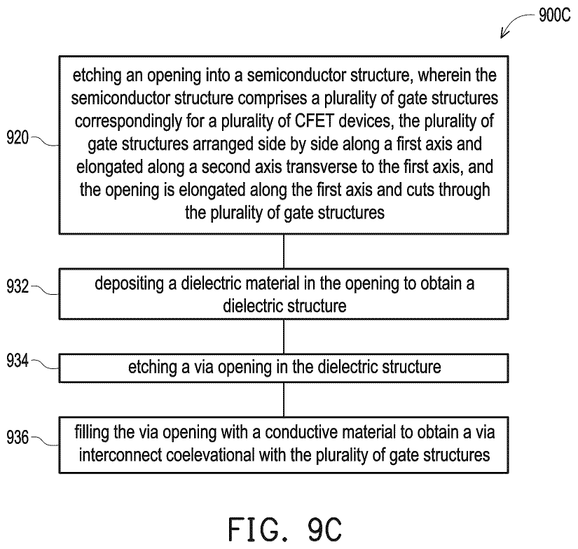

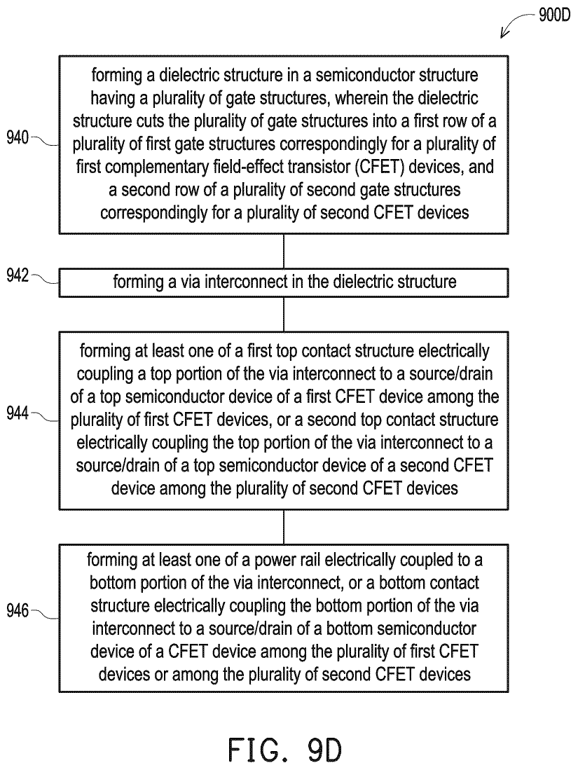

FIG. 9A is a flowchart of a method 900A of generating a layout and using the layout to manufacture an IC device, in accordance with some embodiments. Method 900A is implementable, for example, using an EDA system and/or an integrated circuit (IC) manufacturing system as described herein, in accordance with some embodiments. Regarding method 900A, examples of the layout include the layouts disclosed herein, or the like. Examples of an IC device to be manufactured according to method 900A include one or more of the IC devices disclosed herein.

At operation 902, a layout is generated which, among other things, includes at least one via interconnect embedded in a dielectric structure corresponding to a cut-gate region of a cut-gate mask, as described herein.

At operation 904, based on the layout, at least one of (A) one or more photolithographic exposures are made or (B) one or more semiconductor masks are fabricated or (C) one or more components in a layer of an IC device are fabricated. Examples of operation 904 are described with respect to FIGS. 9B-9D.

FIG. 9B is a flowchart of a method 900B of manufacturing an IC device, in accordance with some embodiments. The flowchart of FIG. 9B shows additional operations that demonstrate one or more examples of procedures implementable in operation 904 of FIG. 9A, in accordance with one or more embodiments. The method 900B comprises operations 920, 922, 924.

At operation 920, an opening is etched into a semiconductor structure. The semiconductor structure comprises a plurality of gate structures correspondingly for a plurality of CFET devices. The plurality of gate structures is arranged side by side along a first axis and elongated along a second axis transverse to the first axis. The opening is elongated along the first axis and cuts through the plurality of gate structures. For example, as described with respect to operation 802 in FIG. 8A, a semiconductor structure 820 comprises a plurality of gate structures 830-870 correspondingly for a plurality of CFET devices. The plurality of gate structures 830-870 is arranged side by side along a first axis, i.e., the X axis, and elongated along a second axis, i.e., the Y axis, transverse to the first axis. As described with respect to operation 804 in FIG. 8A, an opening 882 is etched in to the 820, such that the opening 882 is elongated along the X axis and cuts through the plurality of gate structures 830-870, to severe the gate structures 830-870 into corresponding gate structures 831-871, 832-872.

At operation 922, a conformal layer of a dielectric material is deposited over side walls of the opening, while leaving a middle region of the opening unfilled. For example, as described with respect to operation 806 in FIG. 8A, a conformal layer 885 of a dielectric material is deposited over side walls of the opening 882, while leaving a middle region 886 of the opening 882 unfilled.

At operation 924, the middle region of the opening is filled with a conductive material to obtain a via interconnect which is elongated along the first axis and is electrically isolated from cut ends of the plurality of gate structures by the dielectric material over the side walls of the opening. For example, as described with respect to operation 808 in FIG. 8A, a conductive material is deposited to fill the middle region 886 of the opening 882, to obtain a via interconnect 887. The via interconnect 887 is elongated along the X axis and is electrically isolated from cut ends of the gate structures 831-871 by the conformal layer 885 of the dielectric material over the side walls of the opening 882, as illustrated for example, in FIG. 8A. In at least one embodiment, one or more advantages described herein are achievable by an IC device manufactured in accordance with the method 900B.

FIG. 9C is a flowchart of a method 900C of manufacturing an IC device, in accordance with some embodiments. The flowchart of FIG. 9C shows additional operations that demonstrate one or more examples of procedures implementable in operation 904 of FIG. 9A, in accordance with one or more embodiments. The method 900C comprises operations 920, 932, 934, 936.

Operation 920 is as described with respect to FIG. 9B, i.e., an opening is etched into a semiconductor structure. The semiconductor structure comprises a plurality of gate structures correspondingly for a plurality of CFET devices. The plurality of gate structures is arranged side by side along a first axis and elongated along a second axis transverse to the first axis. The opening is elongated along the first axis and cuts through the plurality of gate structures. For example, as described with respect to operation 802 in FIG. 8A, a semiconductor structure 820 comprises a plurality of gate structures 830-870 correspondingly for a plurality of CFET devices. The plurality of gate structures 830-870 is arranged side by side along a first axis, i.e., the X axis, and elongated along a second axis, i.e., the Y axis, transverse to the first axis. As described with respect to operation 804 in FIG. 8A, an opening 882 is etched in to the 820, such that the opening 882 is elongated along the X axis and cuts through the plurality of gate structures 830-870, to severe the gate structures 830-870 into corresponding gate structures 831-871, 832-872.

At operation 932, a dielectric material is deposited in the opening to obtain a dielectric structure. For example, as described with respect to operation 810 in FIG. 8B, a dielectric material is deposited in the opening 882 to obtain a dielectric structure 895.

At operation 934, a via opening is etched in the dielectric structure. For example, as described with respect to operation 812 in FIG. 8B, a via opening 896 is etched in the dielectric structure 895.

At operation 936, the via opening is filled with a conductive material to obtain a via interconnect co-elevational with the plurality of gate structures. For example, as described with respect to operation 814 in FIG. 8B, a conductive material is deposited to fill the via opening 896 to obtain a via interconnect 897. The via interconnect 897 is co-elevational with the plurality of gate structures 831-837 in a manner similar to that described with respect to FIGS. 3A-3B. In at least one embodiment, one or more advantages described herein are achievable by an IC device manufactured in accordance with the method 900C.

FIG. 9D is a flowchart of a method 900D of manufacturing an IC device, in accordance with some embodiments. The flowchart of FIG. 9D shows additional operations that demonstrate one or more examples of procedures implementable in operation 904 of FIG. 9A, in accordance with one or more embodiments. The method 900D comprises operations 940, 942, 944, 946.

At operation 940, a dielectric structure is formed in a semiconductor structure having a plurality of gate structures. The dielectric structure cuts the plurality of gate structures into (i) a first row of a plurality of first gate structures correspondingly for a plurality of first complementary field-effect transistor (CFET) devices, and (ii) a second row of a plurality of second gate structures correspondingly for a plurality of second CFET devices. For example, as described with respect to operation 802 in FIG. 8A, a semiconductor structure 820 comprises a plurality of gate structures 830-870 is formed. As described with respect to operations 804, 806 in FIG. 8A, and/or operation 810 in FIG. 8B, a dielectric structure 885 or 895 is formed to cut the gate structures 830-870 into (i) a first row first gate structures 831-871 correspondingly for first CFET devices, and (ii) a second row of second gate structures 832-872 correspondingly for second CFET devices.

At operation 942, a via interconnect is formed in the dielectric structure. For example, as described with respect to operations 808 in FIG. 8A, and/or operations 812, 814 in FIG. 8B, a via interconnect 887 or 897 is formed in the dielectric structure 885 or 895.

At operation 944, at least one of (i) a first top contact structure electrically coupling a top portion of the via interconnect to a source/drain of a top semiconductor device of a first CFET device among the plurality of first CFET devices, or (ii) a second top contact structure electrically coupling the top portion of the via interconnect to a source/drain of a top semiconductor device of a second CFET device among the plurality of second CFET devices, is formed. For example, as described with respect to FIGS. 3A, 3B, an MD contact 324 electrically couples a top portion of a via interconnect 360 to a source/drain 322 of a top semiconductor device MN of a CFET device 308.

At operation 946, at least one of (i) a power rail electrically coupled to a bottom portion of the via interconnect, or (ii) a bottom contact structure electrically coupling the bottom portion of the via interconnect to a source/drain of a bottom semiconductor device of a CFET device among the plurality of first CFET devices or among the plurality of second CFET devices, is formed. For example, as described with respect to FIG. 4A, a power rail 391 electrically coupled to a bottom portion of the via interconnect 360. For a further example, as described with respect to FIG. 4B, a bottom contact structure 538 electrically couples the bottom portion of the via interconnect 360 to a source/drain 532 of a bottom semiconductor device MP. In at least one embodiment, one or more advantages described herein are achievable by an IC device manufactured in accordance with the method 900D.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

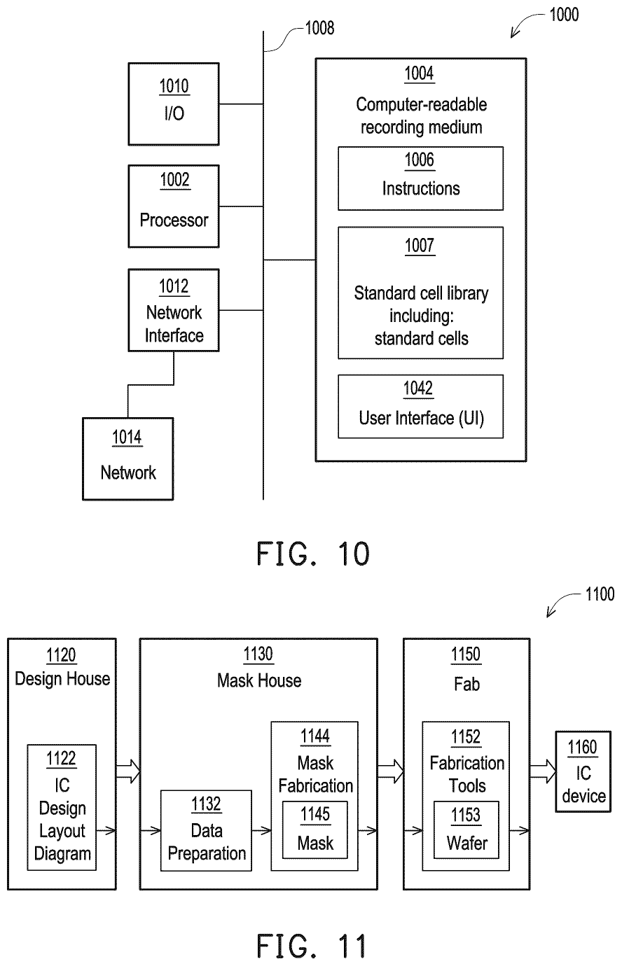

FIG. 10 is a block diagram of an electronic design automation (EDA) system 1000 in accordance with some embodiments.

In some embodiments, EDA system 1000 includes an APR system. Methods described herein of designing layouts represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable recording medium 1004. Recording medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable recording medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable recording medium 1004 are capable of connecting to external elements via network 1014. Processor 1002 is configured to execute computer program code 1006 encoded in computer-readable recording medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable recording medium 1004 is an electronic, magnetic, optical, electromagnetic, infrared, and/or a semiconductor system (or apparatus or device). For example, computer-readable recording medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 1004 includes a compact disk-read only memory (CD-ROM), a compact disk-read/write (CD-R/W), and/or a digital video disc (DVD).

In one or more embodiments, recording medium 1004 stores computer program code 1006 configured to cause system 1000 (where such execution represents (at least in part) the EDA tool) to be usable for performing a portion or all of the noted processes and/or methods. In one or more embodiments, recording medium 1004 also stores information which facilitates performing a portion or all of the noted processes and/or methods. In one or more embodiments, recording medium 1004 stores library 1007 of standard cells including such standard cells as disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable recording medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 11 is a block diagram of an integrated circuit (IC) manufacturing system 1100, and an IC manufacturing flow associated therewith, in accordance with some embodiments. In some embodiments, based on a layout, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout 1122. IC design layout 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout 1122. The design procedure includes one or more of logic design, physical design or place-and-route operation. IC design layout 1122 is presented in one or more data files having information of the geometrical patterns. For example, IC design layout 1122 can be expressed in a GDSII file format or DFII file format.

Mask house 1130 includes data preparation 1132 and mask fabrication 1144. Mask house 1130 uses IC design layout 1122 to manufacture one or more masks 1145 to be used for fabricating the various layers of IC device 1160 according to IC design layout 1122. Mask house 1130 performs mask data preparation 1132, where IC design layout 1122 is translated into a representative data file (“RDF”). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout 1122. In some embodiments, mask data preparation 1132 includes further resolution enhancement techniques (RET), such as off axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1122.

It should be understood that the above description of mask data preparation 1132 has been simplified for the purposes of clarity. In some embodiments, data preparation 1132 includes additional features such as a logic operation (LOP) to modify the IC design layout 1122 according to manufacturing rules. Additionally, the processes applied to IC design layout 1122 during data preparation 1132 may be executed in a variety of different orders.

After mask data preparation 1132 and during mask fabrication 1144, a mask 1145 or a group of masks 1145 are fabricated based on the modified IC design layout 1122. In some embodiments, mask fabrication 1144 includes performing one or more lithographic exposures based on IC design layout 1122. In some embodiments, an electron-beam (e-beam) or a mechanism of multiple e-beams is used to form a pattern on a mask (photomask or reticle) 1145 based on the modified IC design layout 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In some embodiments, an integrated circuit (IC) device comprises a device stack, a top contact structure, a bottom contact structure, a conductor, a via interconnect, and a back side power rail. The device stack comprises a bottom semiconductor device, and a top semiconductor device stacked over the bottom semiconductor device along a thickness direction. The top contact structure is over and in electrical contact with a source/drain of the top semiconductor device. The bottom contact structure is under and in electrical contact with a source/drain of the bottom semiconductor device. The conductor is co-elevational with, and spaced from, the bottom contact structure. The via interconnect extends between and electrically couples the top contact structure and the conductor. The back side power rail is under and electrically coupled to the conductor.

In some embodiments, an integrated circuit (IC) device comprises a plurality of complementary field-effect transistor (CFET) devices arranged along a first axis. Each CFET device of the plurality of CFET devices comprises a bottom semiconductor device, and a top semiconductor device stacked over the bottom semiconductor device along a thickness direction. A first top contact structure is over and in electrical contact with a source/drain of the top semiconductor device of a first CFET device among the plurality of CFET devices. A bottom contact structure is under and in electrical contact with a source/drain of the bottom semiconductor device of the first CFET device or a second CFET device among the plurality of CFET devices. A first via interconnect extends along the first axis and electrically couples the first top contact structure to the bottom contact structure.

In some embodiments, a method comprises etching an opening into a semiconductor structure, depositing a conformal layer of a dielectric material over side walls of the opening while leaving a middle region of the opening unfilled, and filing the middle region of the opening with a conductive material to obtain a via interconnect. The semiconductor structure comprises a plurality of gate structures correspondingly for a plurality of complementary field-effect transistor (CFET) devices. The plurality of gate structures is arranged side by side along a first axis and elongated along a second axis transverse to the first axis. The opening is elongated along the first axis and cuts through the plurality of gate structures. The via interconnect is elongated along the first axis and is electrically isolated from cut ends of the plurality of gate structures by the dielectric material over the side walls of the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a device stack comprising:
a bottom semiconductor device, and
a top semiconductor device stacked over the bottom semiconductor device along a thickness direction;
a top contact structure over and in electrical contact with a source/drain of the top semiconductor device;
a bottom contact structure under and in electrical contact with a source/drain of the bottom semiconductor device;
a conductor co-elevational with, and spaced from, the bottom contact structure;
a via interconnect extending between and electrically coupling the top contact structure and the conductor; and
a back side power rail under and electrically coupled to the conductor.

2. The IC device of claim 1, wherein
the back side power rail and the via interconnect are elongated along a first direction, and
the top contact structure and the bottom contact structure are elongated along a second direction transverse to the first direction.

3. The IC device of claim 2, wherein
a center line of the back side power rail is aligned with a center line of the conductor.

4. The IC device of claim 1, wherein
in a plan view along the thickness direction, the back side power rail overlaps an entirety of the conductor.

5. The IC device of claim 1, wherein
the conductor is co-elevational with gates of the top semiconductor device and the bottom semiconductor device.

6. The IC device of claim 5, further comprising:
a dielectric structure co-elevational with, and in contact with, the gates of the top semiconductor device and the bottom semiconductor device,
wherein the conductor is embedded in the dielectric structure.

7. The IC device of claim 1, wherein
the conductor has a top surface between a top surface and a bottom surface of the top contact structure along the thickness direction.

8. The IC device of claim 1, further comprising:
a further device stack comprising:
a further bottom semiconductor device, and
a further top semiconductor device stacked over the further bottom semiconductor device along the thickness direction;
a further top contact structure over and in electrical contact with a source/drain of the further top semiconductor device;
a further bottom contact structure under and in electrical contact with a source/drain of the further bottom semiconductor device;
a further conductor co-elevational with, and spaced from, the further bottom contact structure; and
a further via interconnect extending between and electrically coupling the further top contact structure and the further conductor,
wherein the back side power rail is electrically coupled to the further conductor.

9. The IC device of claim 1, further comprising:
a further device stack comprising:
a further bottom semiconductor device, and
a further top semiconductor device stacked over the further bottom semiconductor device along the thickness direction;
a further top contact structure over and in electrical contact with a source/drain of the further top semiconductor device;
a further bottom contact structure under and in electrical contact with a source/drain of the further bottom semiconductor device; and
a further conductor co-elevational with, and spaced from, the further bottom contact structure,
wherein the via interconnect extends between and electrically couples the further top contact structure and the further conductor.

10. The IC device of claim 1, further comprising:
a plurality of metal layers over the device stack,
wherein, among the plurality of metal layers, a metal layer closest to the device stack is free of a power rail directly over the via interconnect.

11. An integrated circuit (IC) device, comprising:
a plurality of complementary field-effect transistor (CFET) devices arranged along a first axis, each CFET device of the plurality of CFET devices comprising:
a bottom semiconductor device, and
a top semiconductor device stacked over the bottom semiconductor device along a thickness direction;
a first top contact structure over and in electrical contact with a source/drain of the top semiconductor device of a first CFET device among the plurality of CFET devices;
a bottom contact structure under and in electrical contact with a source/drain of the bottom semiconductor device of the first CFET device or a second CFET device among the plurality of CFET devices; and
a first via interconnect extending along the first axis and electrically coupling the first top contact structure to the bottom contact structure.

12. The IC device of claim 11, wherein
the bottom semiconductor device is of the first CFET device.

13. The IC device of claim 11, wherein
the bottom semiconductor device is of the second CFET device which is spaced, along the first axis, from the first CFET device by at least one further CFET device among the plurality of CFET devices.

14. The IC device of claim 11, further comprising:
a second top contact structure over and in electrical contact with a source/drain of the top semiconductor device of a third CFET device among the plurality of CFET devices;
a back side power rail under the plurality of CFET devices; and
a second via interconnect electrically coupling the second top contact structure to the back side power rail,
wherein the first via interconnect and the second via interconnect are aligned along the first axis.

15. The IC device of claim 14, further comprising:
a third top contact structure over and in electrical contact with a source/drain of the top semiconductor device of a fourth CFET device among the plurality of CFET devices; and
a third via interconnect electrically coupling the third top contact structure to the back side power rail,
wherein the first via interconnect, the second via interconnect and the third via interconnect are aligned along the first axis.

16. The IC device of claim 14, further comprising:
a third top contact structure over and in electrical contact with a source/drain of the top semiconductor device of a fourth CFET device among the plurality of CFET devices,
wherein the second via interconnect further electrically couples the third top contact structure to the back side power rail.

17. The IC device of claim 14, wherein
the second via interconnect intersects multiple planes correspondingly containing multiple gates of different CFET devices among the plurality of CFET devices.

18. The IC device of claim 11, wherein
the first via interconnect intersects multiple planes correspondingly containing multiple gates of different CFET devices among the plurality of CFET devices.

19. The IC device of claim 11, further comprising:
a second top contact structure over and in electrical contact with a source/drain of the top semiconductor device of a third CFET device among the plurality of CFET devices;
a back side power rail under the plurality of CFET devices; and
a plurality of metal layers over the plurality of CFET devices,
wherein the second top contact structure is electrically coupled to the back side power rail by an electrical connection an entirety of which is below the plurality of metal layers.

20. A method, comprising:
etching an opening into a semiconductor structure, wherein
the semiconductor structure comprises a plurality of gate structures correspondingly for a plurality of complementary field-effect transistor (CFET) devices, the plurality of gate structures arranged side by side along a first axis and elongated along a second axis transverse to the first axis, and
the opening is elongated along the first axis and cuts through the plurality of gate structures;
depositing a conformal layer of a dielectric material over side walls of the opening, while leaving a middle region of the opening unfilled; and
filing the middle region of the opening with a conductive material to obtain a via interconnect which is elongated along the first axis and is electrically isolated from cut ends of the plurality of gate structures by the dielectric material over the side walls of the opening.
